(19) United States
(12) Patent Application Publication
(10) Pub. No.: US 2007/0008998 A1
(43) Pub. Date: Jan. 11, 2007

(54) Semiconductor light emitting device

(75) Inventors: Hiroaki Ohta, Kyoto-shi (JP); Toshio Nishida, Kyoto-shi (JP)

Correspondence Address: HOGAN & HARTSON L.L.P., 1999 AVENUE OF THE STARS, SUITE 1400, LOS ANGELES, CA, 90067, US

(73) Assignee: ROHM CO., LTD.

(21) Appl. No.: 11/482,991

(22) Filed: Jul. 6, 2006

(30) Foreign Application Priority Data
Jul. 7, 2005 (JP) JP2005-199432

(51) Int. Cl. H01S 5/00

(52) U.S. Cl. 372/43.01

(57) ABSTRACT

According to the present invention, plural Group III nitride based compound layers with different compositions are placed between an active layer and a hole supply layer for smoothly moving holes to the active layer by using Coulomb forces from polarization charges caused by the difference in composition among the Group III nitride based compound layers.

The present application is based on, and claims priority from, J.P. Application 2005-199432, filed Jul. 7, 2005, the disclosure of which is hereby incorporated by reference herein in its entirety.

### BACKGROUND OF THE INVENTION

1. Field of the Invention

The present invention relates to semiconductor light emitting devices fabricated by depositing plural semiconductor layers.

2. Description of the Related Art

A semiconductor light emitting device has, as a basic structure, a double-hetero junction structure including a semiconductor layer called an active layer which causes recombination of carriers for emitting light, and semiconductor layers called carrier supply layers which sandwich the active layer at its opposite sides for supplying carriers to the active layer. Since the wavelength of emitted light is determined by the band gap of the active layer, a material which can generate light with a desired wavelength is selected as the active layer. In order to facilitate supplying of carriers to the active layer, the carrier supply layers have band gaps wider than the band gap of the active layer. Further, the carrier supply layers are doped with impurities which determine the type of carriers therein.

Further, in order to prevent the impurities added to the carrier supply layers from being diffused to the active layer for improving the optical performance and the reliability, such a semiconductor light emitting device may include semiconductor layers which are non-doped or have lower impurity concentrations, between the carrier layers and the active layer, wherein such semiconductor layers are called barrier layers. Particularly, in the case of a semiconductor laser, the barrier layers are called guide layers, since they offer a light confining effect for reflecting light emitted from the active layer to facilitate stimulated emission (hereinafter, “the semiconductor layers which are non-doped or have lower impurity concentrations and are called guide layers or barrier layers” will be abbreviated to “guide layers”). The structure of the semiconductor light emitting device including the guide layers is called Separate Confinement Hetero (SCH), in some cases. The guide layers are required to have a thickness equal to or greater than a certain thickness in the direction of deposition, in order to offer effects of preventing impurity diffusion and confining light (hereinafter, “the thickness in the direction of deposition” will be abbreviated to “the film thickness”) (for example, refer to “Development of High Output Pulse Semiconductor Lasers for Radars”, K. Abe, Y. Kimura, K. Atsumi and Y. Goto, Denso Technical Review, Vol. 6, No. 1 2001.

“High-Power Pulsed Laser Diode for an Automotive Laser Rader Sensor” (http://www.denso.co.jp/DTR/vol6_no1/dissertation10.pdf)).

### SUMMARY OF THE INVENTION

The film thicknesses of the guide layers can be increased to improve the optical performance and the reliability of the semiconductor light emitting device. However, if the film thicknesses of the guide layers are increased, this will increase the electric resistance and increase the voltage loss in the guide layers, which reduces carrier introduced to the active layer from the carriers supply layers, thereby degrading the efficiency of the semiconductor light emitting device. Accordingly, conventional semiconductor light emitting devices have had the problem of difficulty in attaining both improvement of the optical performance and the reliability and reduction of the electric resistance.

The present invention was made in order to overcome the problem mentioned above and aims at providing semiconductor light emitting devices being capable of smoothly moving holes to the active layer and having a low electric resistance.

In order to attain the object described above, semiconductor light emitting device according to the present invention includes plural semiconductor layers with different compositions, between an active layer and a p-type carrier supply layer (hole supply layer).

More specifically, according to a first aspect of the present invention, there is provided a semiconductor light emitting device including an active layer which causes recombination of electrons and holes, a first semiconductor layer which is deposited on the active layer such that it lies adjacent to the p-type side thereof, has a film thickness in the range of 1 nm or more and 10 nm or less and is made of a Group III nitride based compound with a composition indicated as GaN, a polarization generating layer which is deposited on the first semiconductor layer such that it lies adjacent to the opposite side thereof to the active layer, has a film thickness in the range of 5 nm or more and 100 nm or less and is made of a Group III nitride based compound with a composition indicated as GaₓIn₁₋ₓN (0≦X<1), a second semiconductor layer which is deposited on the polarization generating layer such that it lies adjacent to the opposite side thereof from the first semiconductor layer and is made of a non-doped Group III nitride based compound having a composition indicated as GaN, and a third semiconductor layer which is deposited on the second semiconductor layer such that it lies adjacent to the opposite side thereof from the polarization generating layer and is made of a p-type Group III nitride based compound with a composition indicated as Al_{1-y}Ga_{y}N (0≦y≦1).

There are differences in composition and lattice constant between the first semiconductor layer and the polarization generating layer and between the polarization generating layer and the second semiconductor layer. The difference in composition causes spontaneous polarization. The difference in lattice constant causes lattice distortions, which causes piezo polarization. The spontaneous polarization and piezo polarization (hereinafter, “spontaneous polarization and piezo polarization” will be abbreviated to “polarization”) induce polarization charges between the first semiconductor layer and the polarization generating layer and between the polarization generating layer and the second semiconductor layer.

The polarization charges induce, in the polarization generating layer, an electric field in the direction from the second semiconductor layer to the first semiconductor layer. Further, the electric field continuously and monotonously changes the top level in the valence band and the bottom level in the conduction band of the polarization generating layer such that they are gradually raised in the direction from the second semiconductor layer to the first semiconductor layer. In the polarization generating layer, holes are subjected to Coulomb forces toward the active layer so that the holes can smoothly move toward the active layer from the third semiconductor layer, even when they should move a long distance from the second semiconductor layer to the first semiconductor layer.

Further, the first semiconductor layer preferably has a film thickness of 1 nm or more, in order to function as a final barrier for the active layer. On the other hand, the first semiconductor layer preferably has a film thickness of 10 nm or less, in order to prevent malfunctions of transfer of holes passed through the polarization generating layer, in the first semiconductor layer.

Further, the polarization generating layer preferably has a film thickness in the range of 5 nm or more and 100 nm or less, in order to cause an electric field from polarization charges for changing the top level in the valence band and the bottom level in the conduction band.

Therefore, according to the first aspect of the present invention, there is provided a semiconductor light emitting device being capable of smoothly moving holes to the active layer and having a low electric resistance.

In order to attain the object described above, according to the second aspect of the present invention, there is provided a semiconductor light emitting device including an active layer which causes recombination of electrons and holes, a first semiconductor layer which is deposited on the active layer such that it lies adjacent to the p-type side thereof, has a film thickness in the range of 1 nm or more and 10 nm or less and is made of a Group III nitride based compound with a composition indicated as GaN, a polarization generating layer which is deposited on the first semiconductor layer such that it lies adjacent to the side thereof opposite from the active layer, has a film thickness in the range of 5 nm or more and 100 nm or less and is made of a Group III nitride based compound having a composition indicated as GaₓIn₁₋ₓN (0≦X<1), and a third semiconductor layer which is deposited on the polarization generating layer such that it lies adjacent to the side thereof opposite from the first semiconductor layer and is made of a p-type Group III nitride based compound having a composition indicated as Al_{1-y}Ga_{y}N (0≦y≦1).

For the same reason as that described with respect to the first aspect of the present invention, polarization charges are generated between the first semiconductor layer and the polarization generating layer and between the polarization generating layer and the third semiconductor layer. Holes are subjected to Coulomb forces from the polarization charges in the polarization generating layer. Accordingly, the holes can smoothly move toward the active layer from the third semiconductor layer, even when they should move a long distance from the third semiconductor layer to the first semiconductor layer.

Further, for the same reason as that described with respect to the first aspect of the present invention, the first semiconductor layer preferably has a film thickness in the range of 1 nm or more and 10 nm or less.

Further, for the same reason as that described with respect to the first aspect of the present invention, the polarization generating layer preferably has a film thickness in the range of 5 nm or more and 100 nm or less.

Therefore, according to the second aspect of the present invention, there is provided a semiconductor light emitting device being capable of smoothly moving holes to the active layer and having a low electric resistance.

In order to attain the object, according to a third aspect of the present invention, there is provided a semiconductor light emitting device including an active layer which causes recombination of electrons and holes, a first semiconductor layer which is deposited on the active layer such that it lies adjacent to the p-type side thereof, has a film thickness in the range of 1 nm or more and 10 nm or less and is made of a Group III nitride based compound with a composition indicated as GaN, a super lattice layer which is deposited on the first semiconductor layer such that it lies adjacent to the side thereof opposite from the active layer and is constituted by non-doped Group III nitride based compound thin films with a composition indicated as GaN and Group III nitride based compound thin films with a composition indicated as GaₓIn₁₋ₓN (0≦X<1) which are alternately deposited in the direction of deposition, a second semiconductor layer which is deposited on the superlattice layer such that it lies adjacent to the side thereof opposite from the first semiconductor layer and is made of a non-doped Group III nitride based compound with a composition indicated as GaN, and a third semiconductor layer which is deposited on the second semiconductor layer such that it lies adjacent to the side thereof opposite from the superlattice layer and is made of a p-type Group III nitride based compound with a composition indicated as Al_{1-y}Ga_{y}N (0≦y≦1).

In the following description, “the Group III nitride based compound thin films with a composition indicated as GaₓIn₁₋ₓN (0≦x≦1) in the superlattice layer” will be abbreviated to “the GaInN thin films in the superlattice layer”, and “the non-doped Group III nitride based compound thin films with a composition indicated as GaN in the superlattice layer” will be abbreviated to “the GaN thin films in the superlattice layer”.

For the same reason as that described with respect to the first aspect of the present invention, polarization charges are generated between the first semiconductor layer and the GaInN thin film in the superlattice layer which is adjacent to the first semiconductor layer, between the second semiconductor layer and the GaInN thin film in the superlattice layer which is adjacent to the second semiconductor layer and between the GaN thin films in the superlattice layer and the GaInN thin films in the superlattice layer. The polarization charges generate electric fields in the respective GaInN thin films in the superlattice layer in the direction from the second semiconductor layer to the first semiconductor layer. Further, the electric fields continuously and monotonously change the top levels in the valence bands and the bottom levels in the conduction bands of the respective GaInN thin films in the superlattice layer such that they are gradually raised in the direction from the second semiconductor layer to the first semiconductor layer. In the respective GaInN thin films in the superlattice layer, holes are subjected to Coulomb forces toward the active layer so that the holes can smoothly move toward the active layer from the third semiconductor layer even when they should move a long distance from the second semiconductor layer to the first semiconductor layer.

Further, for the same reason as that described with respect to the first aspect of the present invention, the first semiconductor layer preferably has a film thickness in the range of 1 nm or more and 10 nm or less.

Therefore, according to the third aspect of the present invention, there is provided a semiconductor light emitting device being capable of smoothly moving holes to the active layer and having a low electric resistance.

In order to attain the object, according to a fourth aspect of the present invention, there is provided a semiconductor light emitting device including an active layer which causes recombination of electrons and holes, a first semiconductor layer which is deposited on the active layer such that it lies adjacent to the p-type side thereof, has a film thickness in the range of 1 nm or more and 10 nm or less and is made of a Group III nitride based compound with a composition indicated as GaN, a superlattice layer which is deposited on the first semiconductor layer such that it lies adjacent to the side thereof opposite from the active layer and is constituted by non-doped Group III nitride based compound thin films with a composition indicated as GaN and Group III nitride based compound thin films with a composition indicated as GaₓIn₁₋ₓN (0≦X<1) which are alternately deposited in the direction of deposition, and a third semiconductor layer which is deposited on the superlattice layer such that it lies adjacent to the side thereof opposite from the first semiconductor layer and is made of a p-type Group III nitride based compound with a composition indicated as Al_{1-y}Ga_{y}N (0≦y<1).

For the same reason as that described with respect to the first aspect of the present invention, polarization charges are generated between the first semiconductor layer and the GaInN thin film in the superlattice layer which is adjacent to the first semiconductor layer, between the third semiconductor layer and the GaInN thin film in the superlattice layer which is adjacent to the third semiconductor layer and between the GaN thin films in the superlattice layer and the GaInN thin films in the superlattice layer. Holes are subjected to Coulomb forces from the polarization charges in the respective GaInN thin films in the superlattice layer. Accordingly, the holes can smoothly move toward the active layer from the third semiconductor layer, even when they should move a long distance from the third semiconductor layer to the first semiconductor layer.

Further, for the same reason as that described with respect to the first aspect of the present invention, the first semiconductor layer preferably has a film thickness in the range of 1 nm or more and 10 nm or less.

Therefore, according to the fourth aspect of the present invention, there is provided a semiconductor light emitting device being capable of smoothly moving holes to the active layer and having a low electric resistance.

Preferably, the superlattice layers in the semiconductor light emitting devices according to the third aspect of the present invention and the fourth aspect of the present invention include 10 to 100 pairs of a non-doped Group III nitride based compound thin film with a composition indicated as GaN and a Group III nitride based compound thin film with a composition indicated as GaₓIn₁₋ₓN (0≦x<1).

In order to generate sufficient Coulomb forces to smoothly move holes in the superlattice layer toward the active layer, it is preferable that the superlattice layer includes 10 or more pairs of a GaInN thin film in the superlattice layer and a GaN thin film in the superlattice layer. On the other hand, if the number of GaN thin films having a higher electric resistance in the superlattice layer is increased, this will increase the electric resistance of the superlattice layer and, therefore, it is preferable that the superlattice layer includes 100 pairs or less of a GaInN thin film and a GaN thin film.

Therefore, according to the third aspect of the present invention and the fourth aspect of the present invention, there are provided semiconductor light emitting devices being capable of smoothly moving holes to the active layer and having a low electric resistance.

It is preferable that the active layers in the semiconductor light emitting devices according to the first aspect of the present invention to the fourth aspect of the present invention have a multiple quantum well structure constituted by at least two types of Group III nitride based compound thin films with different compositions indicated as AlₚGa_{q}In_{1-p-q}N (0≦p≦1, 0≦q≦1 and 0≦p+q≦1) which are alternately deposited in the direction of deposition.

The Group III nitride based compounds with compositions indicated as AlₚGa_{q}In_{1-p-q}N (0≦p≦1, 0≦q≦1 and 0≦p+q≦1) are semiconductors which enable controlling their band gaps by changing the compositions defined by p and q. By alternately depositing Group III nitride based compound thin films with different compositions as aforementioned, it is possible to form a multiple quantum well structure (MQW). Since carriers are concentrated in the Group III nitride based compound thin films with the narrower band gap in the MQW, the semiconductor light emitting device employing the MQW can emit light even with a small electric current.

Therefore, according to the first to fourth inventions of the present application, there are provided semiconductor light emitting devices being capable of smoothly moving holes to the active layer and having a low electric resistance.

In the semiconductor light emitting devices according to the first to fourth inventions of the present application, it is desirable that the active layer has a multiple quantum well structure constituted by Group III nitride based compound thin films with relationships of p=0 and q=1 in the composition and Group III nitride based compound thin films with relationships of p=0 and 0≦q<1 in the composition which are alternately deposited in the direction of deposition, and the Group III nitride based compound thin films with relationships of p=0 and 0≦q<1 in the composition in the active layer have a band gap narrower than the band gap of the polarization generating layer or the band gap of the Group III nitride based compound thin films with a composition indicated as GaₓIn₁₋ₓN (0≦x<1) in the superlattice layer.

In the case where the active layer has an MQW constituted by Group III nitride based compound thin films with relationships of p=0 and q=1 in the composition (hereinafter, “the Group III nitride based compound thin films with relationships of p=0 and q=1 in the composition” will be abbreviated to “the GaN thin films in the active layer”) and Group III nitride based compound thin films with relationships of p=0 and 0≦q<1 in the composition (hereinafter, “the Group III nitride based compound thin films with relationships of p=0 and 0≦q<1 in the composition” will be abbreviated to “the GaInN thin films in the active layer”), the GaInN thin films in the active layer have a band gap narrower than the band gap of the polarization generating layer or the band gap of the GaInN thin films in the superlattice layer. With such a band gap structure, it is possible to prevent recombination of holes in the polarization generating layer or the superlattice layer, which causes holes to smoothly move to the active layer.

Therefore, according to the first to fourth inventions of the present application, there are provided semiconductor light emitting devices being capable of smoothly moving holes to the active layer and having a low electric resistance.

In the semiconductor light emitting devices according to the first to fourth inventions of the present application, it is preferable that the Group III nitride based compounds of the first to third semiconductor layers have wurtzite crystal structures, and the direction of deposition of the first to third semiconductor layers is parallel to the directions of the c axes of the crystals of the Group III nitride based compounds of the first to third semiconductor layers.

By depositing the Group III nitride based compounds with wurtzite crystal structures along the direction of the c axis, it is possible to generate the polarization while maintaining certain quality of the semiconductor light emitting device.

Therefore, according to the first to fourth inventions of the present application, there are provided semiconductor light emitting devices being capable of smoothly moving holes to the active layer and having a low electric resistance.

According to the present invention, there are provided semiconductor light emitting devices being capable of smoothly moving holes to the active layer and having a low electric resistance.

### BRIEF DESCRIPTION OF THE DRAWINGS

FIG. 1 is a conceptual illustration of a cross section of a semiconductor light emitting device 901 according to an embodiment of a first aspect of the present invention.

FIG. 2 is a conceptual illustration of a band diagram of the semiconductor light emitting device 901 according to an embodiment of the first aspect of the present invention.

FIG. 3 is a conceptual illustration of a cross section of a semiconductor light emitting device 903 according to another embodiment of the first aspect of the present invention.

FIG. 4 is a conceptual illustration of a band diagram of the semiconductor light emitting device 903 according to another embodiment of the second aspect of the present invention.

FIG. 5 is a conceptual illustration of a cross section of a semiconductor light emitting device 905 according to an embodiment of a second aspect of the present invention.

FIG. 6 is a conceptual illustration of a band diagram of the semiconductor light emitting device 905 according to an embodiment of the second aspect of the present invention.

FIG. 7 is a conceptual illustration of a cross section of a semiconductor light emitting device 907 according to an embodiment of a third aspect of the present invention.

FIG. 8 is a conceptual illustration of a band diagram of the semiconductor light emitting device 907 according to an embodiment of the third aspect of the present invention.

FIG. 9 is a conceptual illustration of a cross section of a semiconductor light emitting device 909 according to another embodiment of the third aspect of the present invention.

FIG. 10 is a conceptual illustration of a band diagram of the semiconductor light emitting device 909 according to another embodiment of the third aspect of the present invention.

FIG. 11 is a conceptual illustration of a cross section of a semiconductor light emitting device 911 according to an embodiment of a fourth aspect of the present invention.

FIG. 12 is a conceptual illustration of a band diagram of the semiconductor light emitting device 911 according to an embodiment of the fourth aspect of the present invention.

FIG. 13 is a conceptual illustration of a cross section of a semiconductor light emitting device 913 according to another embodiment of the first aspect of the present invention.

FIG. 14 is a conceptual illustration of a band diagram of the semiconductor light emitting device 913 according to another embodiment of the first aspect of the present invention.

### DESCRIPTION OF THE PREFERRED EMBODIMENTS

Hereinafter, embodiments of the present invention will be described in detail, with reference to the drawings. However, the present invention is not limited to the following embodiments.

### First Embodiment

According to the present embodiment, there is provided a semiconductor light emitting device including an active layer which causes recombination of electrons and holes, a first semiconductor layer which is deposited on the active layer such that it lies adjacent to the p-type side thereof, has a film thickness in the range of 1 nm or more and 10 nm or less and is made of a Group III nitride based compound with a composition indicated as GaN, a polarization generating layer which is deposited on the first semiconductor layer such that it lies adjacent to the opposite side thereof from the active layer, has a film thickness in the range of 5 nm or more and 100 nm or less and is made of a Group III nitride based compound with a composition indicated as GaₓIn₁₋ₓN (0≦X<1), a second semiconductor layer which is deposited on the polarization generating layer such that it lies adjacent to the opposite side thereof from the first semiconductor layer and is made of a non-doped Group III nitride based compound having a composition indicated as GaN, and a third semiconductor layer which is deposited on the second semiconductor layer such that it lies adjacent to the opposite side thereof from the polarization generating layer and is made of a p-type Group III nitride based compound with a composition indicated as Al_{1-y}Ga_{y}N (0≦y≦1)

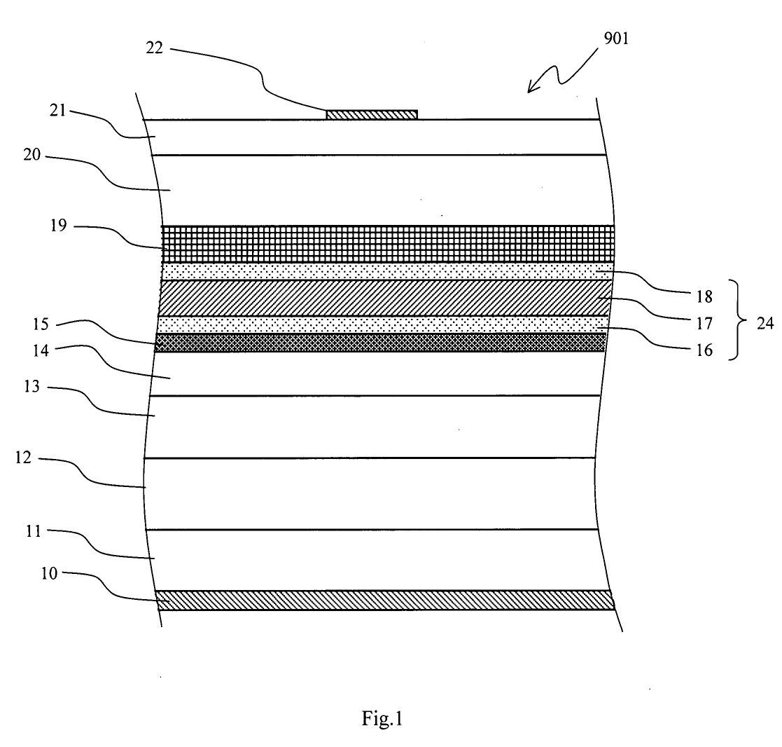

FIG. 1 illustrates a conceptual illustration of a cross sectional area of a semiconductor light emitting device 901 according to an embodiment of the first aspect of the present invention. The semiconductor light emitting device 901 includes an electrode 10, a substrate 11, an n-type foundation layer 12, an electron supply layer 13, a n-side guide layer 14, an active layer 15, a first semiconductor layer 16, a polarization generating layer 17, a second semiconductor layer 18, a third semiconductor layer 19, a hole supply layer 20, a p-type contact layer 21 and a stripe-shaped electrode 22. The semiconductor light emitting device 901 is a double-side electrode type semiconductor light emitting device including an electrode 10 and a stripe-shaped electrode 22 which sandwich semiconductor layers including a substrate 11.

The electrode 10 and the stripe-shaped electrode 22 are placed in order to apply a voltage to the semiconductor light emitting device 901. The electrode 10 functions as a negative electrode while the stripe-shaped electrode 22 functions as a positive electrode. If a rectification characteristic is generated between the electrodes and the semiconductors, this will degrade the electric characteristics of the semiconductor light emitting device. Therefore, it is desirable that the electrode 10 and the stripe-shaped electrode 22 are made of a material which can establish ohmic contact with the semiconductors. Further, it is desirable that the material has a small contact resistance with respect to the wirings from external devices such as a power supply. Accordingly, it is preferable that a buffer material is interposed between the material which contacts with the semiconductors and the material connected to the wirings. For example, as the material of the electrode 10 which contacts with the n-type semiconductors, it is possible to exemplify Ti/Al/Ti/Au and Al/Au. As the material of the stripe-shaped electrode 22 which contacts with the p-type semiconductors, it is possible to exemplify Ni/Au, Pd/Au and Pt/Au.

In order to reduce the contact resistance between the electrode 10 and the substrate 11, it is preferable that the electrode 10 is entirely deposited on the surface of the substrate 11 which is opposite from the surface on which the n-type foundation layer 12 is deposited (hereinafter, “the surface of the substrate 11 which is opposite from the surface on which the n-type foundation layer 12 is deposited” will be referred to as “the back surface of the substrate 11”). On the other hand, the stripe-shaped electrode 22 is placed in a band shape on the p-type contact layer 21, in order to concentrate carriers at a portion of the active layer 15 for supplying them.

The substrate 11 physically supports the semiconductor light emitting device 901. As the substrate of the semiconductor light emitting device 901, a material which preferably enables a semiconductor thin film to grow thereon is selected. For example, gallium nitride (GaN) or silicon carbide (SiC) can be exemplified, in the case of depositing a Group III nitride based compound having a composition indicated as AlₚGa_{q}In_{1-p-q}N (0≦p≦1, 0≦q≦1, 0≦p+q≦1) (hereinafter, “a Group III nitride based compound having a composition of AlₚGa_{q}In_{1-p-q}N (0≦p≦1, 0≦p≦1, 0≦p+q≦1) will be abbreviated to “an AlₚGa_{q}In_{1-p-q}”)

The active layer 15 is a semiconductor layer which causes recombination of electrons and holes for emitting light. Since the wavelength of emitted light depends on the band gap of the active layer 15, a semiconductor which can emit light with a desired wavelength is selected as the active layer 15. Further, it is preferable to select a direct transition semiconductor with a high light emission efficiency, as the material of the active layer 15. The use of an AlₚGa_{q}In_{1-p-q}N compound enables creation a wide band gap by changing its composition, thereby creating a semiconductor light emitting device with a desired wavelength. For example, as the active layer 15, it is possible to exemplify a Group III nitride based compound with a composition indicated as GaₐIn₁₋ₐN, wherein relationships of p=0 and q=a hold (0.8≦a≦0.95, preferably 0.85≦a≦0.90). The active layer 15 has a film thickness in the range of, for example, 10 nm or more and 100 nm or less.

The electron supply layer 13 is a semiconductor layer made of an AlₚGa_{q}In_{1-p-q}N. As the electron supply layer 13, it is possible to exemplify a Group III nitride based compound with a composition indicated as Al_{b}Ga_{1-b}N, wherein the following relationships hold; p=b (0.01≦b≦0.15, preferably 0.05≦b≦0.1) and p+q=1. The electron supply layer 13 is doped with an n-type impurity such as, for example, Si, in order to increase the electron concentration therein. The electron supply layer 13 may have an impurity concentration in the range of, for example, 5×10¹⁷ cm⁻³ to 1×10¹⁹ cm⁻³. The electron supply layer 13 preferably has a film thickness in the range of 300 nm or more and 2000 nm or less, more preferably in the range of 400 nm or more and 1200 nm or less.

Further, in the case where the semiconductor light emitting device 901 is a semiconductor laser, it is preferable that the electron supply layer 13 has a film thickness of 1000 nm, in order to function as a clad layer for supplying electrons to the active layer 15, wherein a relationship of b=0.08 holds (Al_{0.08}Ga_{0.92}N compound) and also the concentration of Si as impurity is 3×10¹⁸ cm⁻³.

The n-side guide layer 14 is a semiconductor layer made of an AlₚGa_{q}In_{1-p-q}N compound. In order to prevent the impurity from being diffused to the active layer 15, the n-side guide layer 14 has an impurity concentration lower than the concentration of impurity added to the electron supply layer 13. Also, the n-side guide layer 14 is not necessarily required to be doped with impurity. Further, the n-side guide layer 14 has a band gap greater than the band gap of the active layer 15, but smaller than the band gap of the electron supply layer 13. More specifically, the n-side guide layer 14 is made of, for example, a GaN compound with a composition of p=0 and q=1. Also, the n-side guide layer 14 may have a composition of p=0 and 0.95≦q≦1. The n-side guide layer 14 preferably has a thickness in the range of 20 nm or more and 200 nm or less, more preferably in the range of 50 nm or more and 150 nm or less.

Further, in the case where the semiconductor light emitting device 901 is a semiconductor laser, the n-side guide layer 14 is preferably made of a low-doped GaN compound having a film thickness of 100 nm and a concentration of Si as impurity in the range of 0 cm⁻³ or more and 1×10¹⁸ cm⁻³ or less, in order to offer an light confining effect for facilitating stimulated emission by reflecting the light generated from the active layer 15.

The hole supply layer 20 is a semiconductor layer made of an AlₚGa_{q}In_{1-p-q} N compound. The hole supply layer 20 may be made of, for example, a III nitride compound with a composition indicated as Al_{c}Ga_{1-c}N, wherein a relationship of p=c holds (0.01≦c≦0.15, preferably 0.05≦c≦0.1) and a relationship of p+q=1 holds. The hole supply layer 20 is doped with a p-type impurity such as Mg, in order to increase the carrier concentration thereof. The impurity concentration thereof may be, for example, in the range of 5×10¹⁸ cm⁻³ or more and 1×10²⁰ cm⁻³ or less. The hole supply layer 20 preferably has a film thickness in the range of 100 nm or more and 2000 nm or less, more preferably in the range of 200 nm or more and 500 nm or less.

Further, in the case where the semiconductor light emitting device 901 is a semiconductor laser, it is preferable that the hole supply layer 20 has a film thickness of 500 nm, a composition satisfying a relationship of c=0.08 (an Al_{0.08}Ga_{0.92}N compound) and a concentration of Mg as impurity of 3×10¹⁹ cm⁻³, in order to function as a clad layer for supplying holes to the active layer 15.

The first semiconductor layer 16 is a semiconductor layer made of a deposited Group III nitride based compound with a composition of GaN and a wurtzite crystal structure. The first semiconductor layer 16 functions as a barrier for the active layer 15. The first semiconductor layer 16 is formed to have a film thickness in the range of 1 nm or more and 10 nm or less, preferably in the range of 2 nm or more and 8 nm or less. The first semiconductor layer 16 may be doped with Si as impurity.

The polarization generating layer 17 is made of a deposited Group III nitride based compound with a wurtzite crystal structure and a composition indicated as GaₓIn₁₋ₓN (0≦x≦1). In order to prevent the occurrence of recombination of carriers in the polarization generating layer 17, it is preferable that the polarization generation layer 17 has a band gap greater than the band gap of the active layer 15. More specifically, in the composition, x is, for example, in the range of 0.95≦x≦0.99, preferably in the range of 0.98≦x≦0.99. Further, the polarization generating layer 17 is preferably formed to have a film thickness in the range of 5 nm or more and 100 nm or less, more preferably in the range of 10 nm or more and 100 nm or less and, most preferably in the range of 20 nm or more and 80 nm or less. The polarization generating layer 17 is a semiconductor layer having the function of smoothly moving holes which are carriers.

The second semiconductor layer 18 is a Group III nitride based compound with a composition of GaN and a wurtzite crystal structure. The second semiconductor layer 18 is not doped and has a high electric resistance. The second semiconductor layer 18 is formed to have a film thickness in the range of 1 nm or more and 10 nm or less, preferably in the range of 2 nm or more and 8 nm or less.

A phenomenon called carrier overflow may occur. Such carrier overflow is a phenomenon in which electrons exceed the barrier of the quantum well of the active layer and move to the p-type side semiconductor layers by receiving thermal energy from heat generation occurred along with light emission by the semiconductor light emitting device. The overflowed electrons become, in the p-type semiconductor layers, ineffective carriers, which do not contribute to light emission, to reduce the light emission efficiency of the semiconductor light emitting device. Therefore, it is necessary to reduce overflowed electrons.

The third semiconductor layer 19 is called an electron barrier layer and prevents carrier overflow. The third semiconductor layer 19 is made of a p-type Group III nitride based compound with a composition indicated as Al_{1-y}Ga_{y}N (0≦y≦1). The third semiconductor layer 19 may be made of a Group III nitride based compound with a wurtzite crystal structure. The third semiconductor layer 19 is required to have a wide band gap and has a composition of 0≦y≦1, preferably 0.7≦y≦0.9, more preferably 0.75≦y≦0.85. For example, the third semiconductor layer 19 has a film thickness in the range of 10 nm or more and 30 nm or less, preferably in the range of 15 nm or more and 25 nm or less.

The third semiconductor layer 19 has a wide band gap and has a high bottom level of the transmission band since it is of a p-type and, accordingly, even electrons which have received thermal energy as previously described can not pass through the third semiconductor layer 19 to move to the p-type side semiconductor layers. Consequently, the third semiconductor layer 19 can reduce ineffective carriers, thereby increasing the light emission efficiency of the semiconductor light emitting device.

Further, in the case where the semiconductor light emitting device 901 is a semiconductor laser, a relationship of, for example, y=0.2 holds (Al_{0.8}Ga_{0.2}N compound) in the composition of the third semiconductor layer 19, and the third semiconductor layer 19 is doped with Mg as impurity, in order to make it to be of a p-type. The third semiconductor layer 19 has an impurity concentration in the range of, for example, 1×10¹⁹ cm⁻³ or more and 1×10²⁰ cm⁻³ or less, preferably an impurity concentration of 5×10¹⁹ cm⁻³. The third semiconductor layer 19 preferably has a film thickness of 20 nm.

Further, the p-side guide layer 24 includes the first semiconductor layer 16, the polarization generating layer 17 and the second semiconductor layer 18.

The p-type contact layer 21 is a semiconductor layer which is in ohmic contact with the stripe-shaped electrode 22. For example, the p-type contact layer 21 is made of, for example, a GaN compound with a film thickness in the range of 10 nm or more and 100 nm or less. In the case where the p-type contact layer 21 is made of a GaN compound, it may be doped with Mg as impurity, for example.

Then-type foundation layer 12 may be made of, for example, an n-type GaN compound which is doped with Si as impurity and has a film thickness in the range of 1 μm or more and 5 μm or less. The impurity concentration thereof is, for example, in the range of 5×10¹⁷ cm⁻³ or more and 1×10¹⁹ cm⁻³ or less. The n-type foundation layer 12 can improve the crystallinity of the electron supply layer 13.

The respective semiconductor layers in the semiconductor light emitting device 901 are deposited through a metal organic chemical vapor deposition method (hereinafter, “a metal organic chemical vapor deposition method” will be abbreviated to “a MOCVD method”). The MOCVD method is a method of introducing reactive gas into a reactor (chamber), causing thermal decomposition of the reactive gas on a substrate which is secured in the chamber and maintained at a temperature in the range of 600° C. to 1100° C. to epitaxially grow a thin film thereon. Such an MOCVD method enables semiconductor layers to be deposited easily with different compositions and film thicknesses, by controlling fabrication parameters such as the flow rate and the concentration of the reactive gas, the reaction time and temperature, the type of dilution gas.

In the case where the n-type foundation layer 12, the electron supply layer 13, the n-side guide layer 14, the active layer 15, the first semiconductor layer 16, the polarization generating layer 17, the second semiconductor layer 18, the third semiconductor layer 19, the hole supply layer 20 and the p-type contact layer 21 are made of AlₚGa_{q}In_{1-p-q} N compounds, in the MOCVD method, as group-III elements, Ga(CH₃)₃ (trimethylgallium, hereinafter, abbreviated to “TMG”), In(C₂H₅)₃ (trimethylindium, hereinafter, abbreviated to “TMI”) and Al(CH₃)₃ (trimethylaluminum, hereinafter, abbreviated to “TMA”) are bubbled with hydrogen or nitrogen, which are carrier gases, to create vapor for use as material gas, and also ammonia gas is employed for forming a nitride. Further, as impurity, it is possible to employ, to add the material gas, CP₂Mg (cyclopentadienyl magnesium) as a p-type dopant or SiH₄ (silane) as an n-type dopant. The material gas is introduced into the chamber through hydrogen or nitrogen carrier gas. The MOCVD method enables a desired AlₚGa_{q}In_{1-p-q}N compound to grow, by setting, as fabrication parameters, the mixing ratio of mixed gas consisting of CP₂Mg or SiH₄, TMG, TMI, TMA and ammonia, the flow rate of the mixed gas and the substrate temperature. The MOCVD method enables the film thickness of the AlₚGa_{q}In_{1-p-q}N compound to be controlled with the reaction time. Further, by changing the fabrication parameters at predetermined times during reaction, it is possible to successively deposit AlₚGa_{q}In_{1-p-q}N compounds with different compositions.

Such a semiconductor light emitting device 901 can be formed by successively depositing, on a substrate 11, an n-type foundation layer 12, an electron supply layer 13, an n-side guide layer 14, an active layer 15, a first semiconductor layer 16, a polarization generating layer 17, a second semiconductor layer 18, a third semiconductor layer 19, a hole supply layer 20 and a p-type contact layer 21.

More specifically, the semiconductor light emitting device 901 is fabricated as follows. A substrate 11 is introduced into the chamber, then carrier gas is substituted for the inside of the chamber and also the temperature of the substrate 11 is raised to a temperature in the range of about 600° C. to 1100° C.

Then, a mixed gas consisting of TMG, TMI, TMA, ammonia and SiH₄ with a mixing ratio which can grow an n-type foundation layer 12 is introduced thereto to cause reaction on the substrate 11 for a predetermined time of period. Due to the reaction, an n-type foundation layer 12 is deposited thereon. For example, in the case where the n-type foundation layer 12 is made of a GaN compound, a mixed gas consisting of TMG, ammonia and SiH₄ is employed.

Next, a mixed gas consisting of TMG, TMI, TMA, ammonia and SiH₄ with a mixing ratio which can grow an electron supply layer 13 is introduced thereto to cause reaction on the n-type foundation layer 12 for a predetermined time period. Due to the reaction, an electron supply layer 13 is deposited on the n-type foundation layer 12. For example, in the case where the electron supply layer 13 is made of a Group III nitride based compound indicated as Al_{b}Ga_{1-b}N, mixed gas consisting of TMG, TMA, ammonia and SiH₄ is employed.

Similarly, a mixed gas with a predetermined mixing ratio is introduced thereto to deposit an n-side guide layer 14, an active layer 15, a first semiconductor layer 16, a polarization generating layer 17, a second semiconductor layer 18, a third semiconductor layer 19, a hole supply layer 20 and a p-type contact layer 21, in the mentioned order. Further, the Group III nitride based compounds of the first semiconductor layer 16, the polarization generating layer 17 and the second semiconductor layer 18 are deposited such that the direction of deposition is parallel to the direction of the c-axis of the crystal.

Also, it is possible to employ a molecular beam epitaxy deposition method (MBE method), as a method for depositing the Group III nitride based compounds on the substrate 11.

After the deposition of the p-type contact layer 21, the material of a stripe-shaped electrode 22 is deposited on the p-type contact layer 21, and the material of an electrode 10 is deposited on the back surface of the substrate 11. It is possible to employ a vacuum deposition method, as a method for depositing the materials of the electrode. Further, prior to the deposition of the electrodes, annealing may be performed in an atmosphere of N₂ at a temperature in the range of 600° C. to 900° C.

After the deposition of the materials of the electrodes, a stripe-shaped electrode 22 is formed. It is possible to employ a lithography technique and dry etching, as a method for forming a stripe-shaped electrode 22. A stripe-shaped resist pattern is formed through a lithography technique and, then, the material of the stripe-shaped electrode 22 is etched into a stripe shape. By using an etching gas which offers a high selection ratio between the material of the stripe-shaped electrode 22 and the p-type contact layer 21 made of, for example, a GaN compound, it is possible to employ the p-type contact layer 21, as an etching stop layer. As previously described, by using a lithography technique and dry etching, it is possible to preferably etch the material of the stripe-shaped electrode 22 at the portion thereof which is not covered with the resist pattern. By removing the resist subsequently, the formation of the stripe-shaped electrode 22 can be completed.

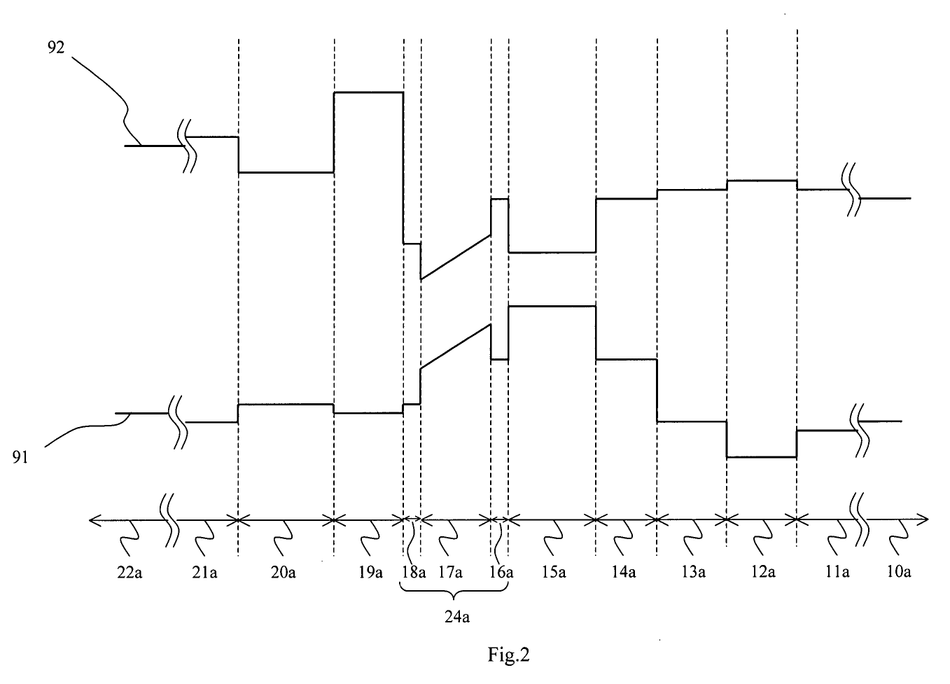

FIG. 2 illustrates a conceptual illustration of a band diagram of the semiconductor light emitting device 901. In FIG. 2, 91 is the top level in the valence band and 92 is the bottom level in the conduction band. Further, 10a indicates the area of the electrode 10, 11a indicates the area of the substrate 11, 12a indicates the area of the n-type foundation layer 12, 13a indicates the area of the electron supply layer 13, 14a indicates the area of the n-side guide layer 14, 15a indicates the area of the active layer 15, 16a indicates the area of the first semiconductor layer 16, 17a indicates the area of the polarization generating layer 17, 18a indicates the area of the second semiconductor layer 18, 19a indicates the area of the third semiconductor layer 19, 20a indicates the area of the hole supply layer 20, and 21a indicates the area of the p-type contact layer 21. Further, in FIG. 2, illustration of the band gaps of the electrode 10 and the substrate 11 and the band gaps of the p-type contact layer 21 and the stripe-shaped electrode 22 is partially omitted.

In the n-side with respect to the active layer 15, the band gaps of the active layer 15, the n-side guide layer 14, the electron supply layer 13 and the substrate 11 are gradually widened in the mentioned order, while the bottom levels 92 in the conduction bands of the electron supply layer 13, the n-side guide 14 and the active layer 15 are gradually lowered in the mentioned order.

On the other hand, the band gaps of the first semiconductor layer 16, the polarization generating layer 17, the second semiconductor layer 18, the third semiconductor layer 19, the hole supply layer 20 and the p-type contact layer 21, which are in the p side with respect to the active layer 15, are as follows.

The first semiconductor layer 16 has a band gap equal to that of the second semiconductor layer 18. The top level 91 in the valence band of the second semiconductor layer 18 is higher than the top level 91 in the valence band of the first semiconductor layer 16. Further, the bottom level 92 in the conduction band of the second semiconductor layer 18 is lower than the bottom level 92 in the conduction band of the first semiconductor layer 16.

Polarization is generated between the polarization generating layer 17 and the first semiconductor layer 16 adjacent thereto and between the polarization generating layer 17 and the second semiconductor layer 18 adjacent thereto, which induces an electric field in the polarization generating layer 17, in the direction from the second semiconductor layer 18 to the first semiconductor layer 16. Accordingly, the electric field raises the top level 91 in the valence band and the bottom level 92 in the conduction band of the polarization generating layer 17, gradually in the direction from the second semiconductor layer 18 to the first semiconductor layer 16.

The third semiconductor layer 19 contains Al in its composition and has a band gap wider than the band gap of the second semiconductor layer 18 adjacent thereto.

Accordingly, in the p side with respect to the active layer 15, the top levels 91 in the valence bands of the third semiconductor layer 19, the second semiconductor layer 18, the first semiconductor layer 16 and the active layer 15 are gradually raised in the mentioned order.

As illustrated in the band diagram of FIG. 2, the active layer 15 is sandwiched between the n-side guide layer 14 and the first semiconductor layer 16 having wider band gaps than that of the active layer 15 so that the active layer 15, the n-side guide layer 14 and the first semiconductor layer 16 form a quantum well structure.

In the semiconductor light emitting device 901, carriers move as follows. Electrons introduced from the electrode 10 can smoothly move toward the active layer 15, in the substrate 11, the n-type foundation layer 12 and the electron supply layer 13 in which electrons form majority carriers. Since the n-side guide layer 14 has a band gap narrower than the band gap of the electron supply layer 13, the electrons move along the bottom level 92 in the conduction band to the n-side guide layer 14 which stabilizes their energy. Further, for the same reason, electrons move from the n-side guide layer 14 to the active layer 15 and are concentrated at the bottom level 92 in the conduction band of the active layer 15 which forms the quantum well.

On the other hand, holes introduced from the stripe-shaped electrode 22 can smoothly move toward the active layer 15, in the p-type contact layer 21, the hole supply layer 20 and the third semiconductor layer 19 in which holes form majority carriers. Since the third semiconductor layer 19 has a band gap wider than the band gap of the second semiconductor layer 18, the holes move along the top level 91 in the valence band to the second semiconductor layer 18 which stabilizes their energy. Further, for the same reason, holes move from the second semiconductor layer 18 to the polarization generating layer 17. The holes are subjected to Coulomb forces from the electric field in the polarization generating layer 17 and smoothly move toward the first semiconductor layer 16. The holes which have been subjected to Coulomb forces from the electric field can pass through the first semiconductor layer 16 having a small film thickness in the range of 1 nm or more and 10 nm or less and are concentrated at the top level 91 in the valence band of the active layer 15.

The electrons and the holes concentrated in the active layer 15 are recombined and, thus, the semiconductor light emitting device 901 emits, from the active layer 15, light with a wavelength according to the band gap, which is indicated as the interval between the top level 91 in the valence band and the bottom level 92 in the conduction band in the quantum well.

Since a hole which is a carrier in the p-type semiconductors has an effective mass greater than that of an electron and has greater difficulty in being moved than an electron, there has been a need for greater energy for introducing holes in the active layer. The polarization generating layer 17 can reduce the energy, thereby reducing the electric resistance of the semiconductor light emitting device 901.

Further, even if the film thickness of the p-side guide layer 24 is increased in order to improve the optical performance and the reliability, holes can smoothly move in the polarization generating layer 17, which prevents the reduction of holes introduced to the active layer. Accordingly, the semiconductor light emitting device 901 can attain both improvement of the optical performance and the reliability and reduction of the electrical resistance.

Further, the semiconductor light emitting device 901 can reduce the threshold current, which increases the brightness of light emission, thereby increasing the light emission efficiency.

### Second Embodiment

In the present embodiment, it is preferable that the active layer has a multiple quantum well structure constituted by thin films made of at least two types of Group III nitride based compounds with different compositions indicated as AlₚGa_{q}In_{1-p-q}N (0≦p≦1, 0≦q≦1, and 0≦p+q≦1) which are alternately arranged in the direction of deposition.

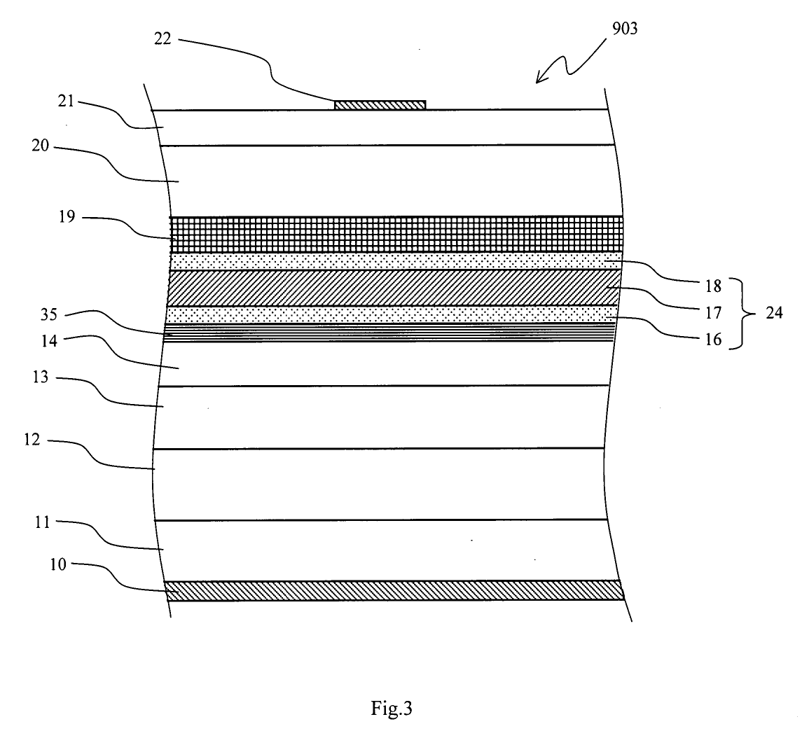

FIG. 3 illustrates a conceptual illustration of a cross section of a semiconductor light emitting device 903 according to another embodiment of the first aspect of the present invention. In FIG. 3, the same reference numerals as those used in FIG. 1 indicate the same semiconductor layers, the same substrate or the same electrodes. The semiconductor light emitting device 903 is different from the semiconductor light emitting device 901 of FIG. 1 in that the semiconductor light emitting device 903 does not include the active layer 15 in the semiconductor light emitting device 901, but includes an active layer 35.

The active layer 35 is an MQW semiconductor layer made of at least two types of AlₚGa_{q}In_{1-p-q}N compound thin films with different compositions which are alternately deposited. Since the band gap of an AlₚGa_{q}In_{1-p-q}N compound is varied depending on its composition, the Group III nitride based compound thin films with a wider band gap, out of the two types of Group III nitride based compound thin films, are utilized as barriers, while the Group III nitride based compound thin films with a narrower band gap are utilized as quantum wells. Further, in the following description, “the Group III nitride based compound thin films with a wider band gap in the active layer 35” will be referred to as “the barrier thin films in the active layer 35”, while “the Group III nitride based compound thin films with a narrower band gap in the active layer 35” will be referred to as “the quantum well thin films in the active layer 35”. Recombination of electrons and holes occurs in the quantum well thin films in the active layer 35, which emits light with a wavelength according to the band gap of the quantum well thin films in the active layer 35. Namely, the wavelength of emitted light can be determined by the composition of the quantum well thin films in the active layer 35.

For example, the barrier thin films in the active layer 35 are made of a Group III nitride based compound with a composition indicated as Ga_{d}In_{1-d}N, wherein relationships of p=0 and q=d hold (0.95≦d≦1, preferably 0.97≦d≦1). On the other hand, the quantum well thin films in the active layer 35 are made of, for example, a Group III nitride based compound with a composition of GaₑIn₁₋ₑN, wherein relationships of p=0 and q=e hold (e<d and 0.80≦e≦0.95, preferably e<d and 0.85≦e≦0.9).

The barrier thin films in the active layer 35 preferably have a film thickness in the range of 5 nm or more and 20 nm or less, more preferably in the range of 7 nm or more and 15 nm or less.

The quantum well thin films in the active layer 35 preferably have a film thickness in the range of 1 nm or more and 10 nm or less, more preferably in the range of 3 nm or more and 5 nm or less.

Preferably, there are provided two pairs or more three pairs or less of a barrier thin film and a quantum well thin film in the active layer 35.

Further, in the case where the semiconductor light emitting device 903 is a semiconductor laser, it is preferable that the active layer 35 has a multiple quantum well structure constituted by thin films made of a Group III nitride based compound with a composition of p=0 and q=1 and thin films made of a Group III nitride based compound with a composition of p=0 and 0≦q≦1 which are alternately deposited in the direction of deposition, wherein the thin films made of the Group III nitride based compound with a composition of p=0 and 0≦q<1 in the active layer 35 have a band gap narrower than the band gap of the polarization generating layer 17.

More specifically, for example, the quantum well thin films in the active layer 35 are made of a Group III nitride based compound with a composition of Ga_{0.87}In_{0.13}N, namely e=0.87, while the barrier thin films in the active layer 35 are made of a GaN compound, namely d=1. Further, for example, the quantum well thin films in the active layer 35 have a film thickness of 3 nm, while the barrier thin films in the active layer 35 have a film thickness of 10 nm.

In the semiconductor light emitting device 903, the active layer 35 is placed between the n-side guide layer 14 and the first semiconductor layer 16, instead of the active layer 15 of the semiconductor light emitting device 901 in FIG. 1.

The active layer 35 can be formed by successively and alternately depositing two types of AlₚGa_{q}In_{1-p-q} N compound thin films, through a MOCVD method as described with respect to the semiconductor light emitting device 901 of FIG. 1. Accordingly, such a semiconductor light emitting device 903 can be formed by depositing, through an MOCVD method, an n-type foundation layer 12, an electron supply layer 13, an n-side guide layer 14, an active layer 35, a first semiconductor layer 16, a polarization generating layer 17, a second semiconductor layer 18, a third semiconductor layer 19, a hole supply layer 20 and a p-type contact layer 21, in the mentioned order, on a substrate 11. Further, the Group III nitride based compounds of the first semiconductor layer 16, the polarization generating layer 17 and the second semiconductor layer 18 are deposited such that the direction of deposition is parallel to the direction of the c axis of the crystal.

Further, an electrode 10 and a stripe-shaped electrode 22 can be also formed as described with respect to the semiconductor light emitting device 901 of FIG. 1.

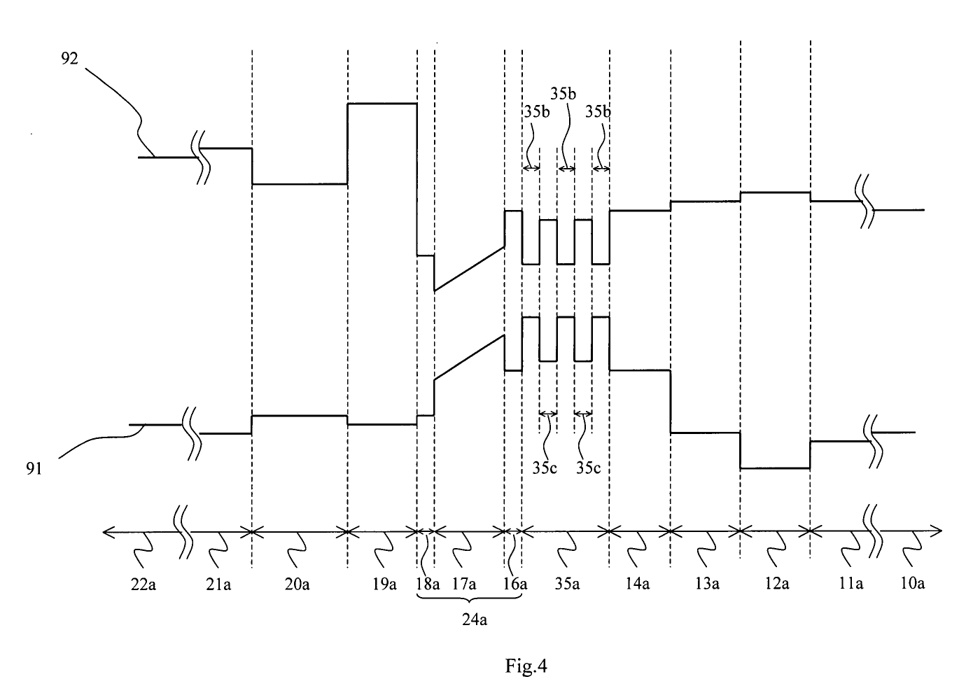

FIG. 4 illustrates a conceptual illustration of a band diagram of the semiconductor light emitting device 903. In FIG. 4, the same reference numerals as those used in the band diagram of FIG. 2 illustrate the areas or the energy levels of the same semiconductor layers. FIG. 4 is different from FIG. 2 in that the active layer area of the active layer 35 indicated as 35a is substituted for the area of the active layer 15 indicated as 15a. In FIG. 4, the active layer 35 includes three quantum wells.

In the area 35a of the active layer 35, 35b indicates the areas of the quantum well thin films in the active layer 35, while 35c indicates the areas of the barrier thin films in the active layer 35, wherein the quantum well thin films in the active layer 35 are designed to have a band gap narrower than the band gap of the n-side guide layer 14 and the band gap of the polarization generating layer 17.

As described with reference to the band diagram of the semiconductor light emitting device 901 of FIG. 2, in the n side with respect to the active layer 35, the bottom levels 92 in the conduction bands of the electron supply layer 13, the n-side guide layer 14 and the quantum well thin films in the active layer 35 are gradually lowered in the mentioned order.

Similarly, in the p side with respect to the active layer 35, the top levels 91 in the valence bands of the third semiconductor layer 19, the second semiconductor layer 18, the first semiconductor layer 16 and the quantum well thin films in the active layer 35 are gradually raised in the mentioned order.

In the semiconductor light emitting device 903, carriers move as described with respect to the semiconductor light emitting device 901 of FIG. 2. Namely, electrons introduced from the electrode 10 are concentrated at the bottom level 92 in the conduction band of the quantum well thin films in the active layer 35, while holes introduced from the stripe-shaped electrode 22 are concentrated at the top level 91 in the valence band of the quantum well thin films in the active layer 35.

Recombination of the electrons and the holes concentrated in the quantum well thin films in the active layer 35 occurs, which causes the semiconductor light emitting device 35 to emit, from the active layer 35, light with a wavelength according to the band gap, which is indicated as the interval between the top level 91 in the valence band and the bottom level 92 in the conduction band of the quantum wells in the active layer 35.

Accordingly, the semiconductor light emitting device 903 can offer the same effects as those described with respect to the semiconductor light emitting device 901 of FIG. 1.

### Third Embodiment

According to the present embodiment, there is provided a semiconductor light emitting device including an active layer which causes recombination of electrons and holes, a first semiconductor layer which is deposited on the active layer such that it lies adjacent to the p-type side thereof, has a film thickness in the range of 1 nm or more and 10 nm or less and is made of a Group III nitride based compound having a composition indicated as GaN, a polarization generating layer which is deposited on the first semiconductor layer such that it lies adjacent to the side thereof opposite from the active layer, has a film thickness in the range of 5 nm or more and 100 nm or less and is made of a Group III nitride based compound having a composition indicated as GaₓIn₁₋ₓN (0≦X<1), and a third semiconductor layer which is deposited on the polarization generating layer such that it lies adjacent to the side thereof opposite from the first semiconductor layer and is made of a p-type Group III nitride based compound having a composition indicated as Al_{1-y}Ga_{y}N (0≦y≦1).

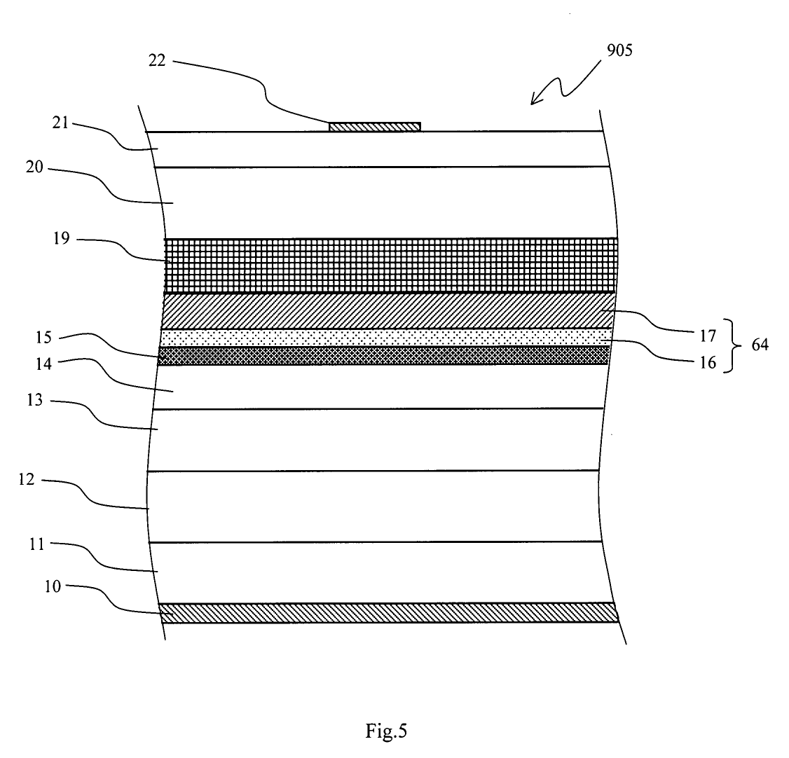

FIG. 5 illustrates a conceptual illustration of a cross section of a semiconductor light emitting device 905 according to an embodiment of the second aspect of the present invention. In FIG. 5, the same reference numerals as those used in FIG. 1 indicate the same semiconductor layers, the same substrate or the same electrodes. The semiconductor light emitting device 905 is different from the semiconductor light emitting device 901 of FIG. 1 in that the semiconductor light emitting device 905 does not include the second semiconductor layer 18 in the semiconductor light emitting device 901 and the polarization generating layer 17 and the third semiconductor layer 19 are adjacent to each other.

Further, a p-side guide layer 64 includes the first semiconductor layer 16 and the polarization generating layer 17.

Such a semiconductor light emitting device 905 can be formed by depositing, on a substrate 11, an n-type foundation layer 12, an electron supply layer 13, an n-side guide layer 14, an active layer 15, a first semiconductor layer 16, a polarization generating layer 17, a third semiconductor layer 19, a hole supply layer 20 and a p-type contact layer 21, in the mentioned order, through an MOCVD method as described with respect to the semiconductor light emitting device 901. Further, the Group III nitride based compounds of the first semiconductor layer 16, the polarization generating layer 17 and the third semiconductor layer 19 are deposited such that the direction of deposition is parallel to the direction of the c axis of the crystal.

Further, an electrode 10 and a stripe-shaped electrode 22 can be also formed as described with respect to the semiconductor light emitting device 901 of FIG. 1.

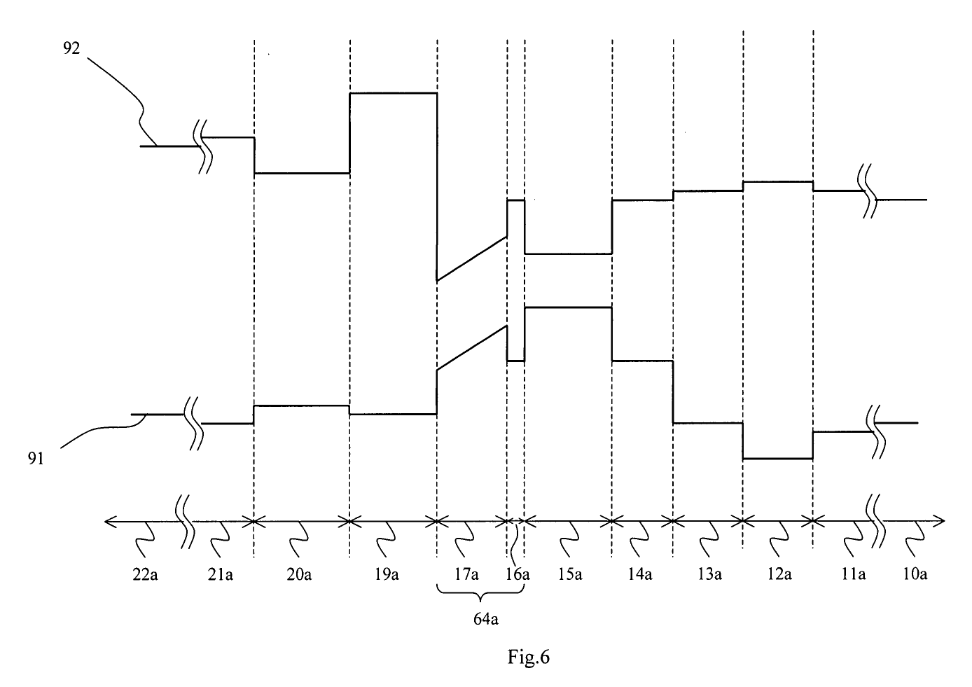

FIG. 6 illustrates a conceptual illustration of a band diagram of the semiconductor light emitting device 905. In FIG. 6, the same reference numerals as those used in the band diagram of FIG. 2 illustrate the areas or the energy levels of the same semiconductor layers. The band diagram of FIG. 6 is different from the band diagram of FIG. 2 in that the band diagram of FIG. 6 does not include the area of the second semiconductor layer 18 indicated by 18a in the band diagram of FIG. 2.

As previously described with reference to the band diagram of the semiconductor light emitting device 901 of FIG. 2, in the n side with respect to the active layer 15, the bottom levels 92 in the conduction bands of the electron supply layer 13, the n-side guide layer 14 and the active layer 15 are gradually lowered in the mentioned order.

The first semiconductor layer 16, the polarization generating layer 17, the third semiconductor layer 19, the hole supply layer 20 and the p-type contact layer 21, which are in the p side with respect to the active layer 15, have band gaps as follows.

Polarization is generated between the polarization generating layer 17 and the first semiconductor layer 16 adjacent thereto and between the polarization generating layer 17 and the third semiconductor layer 19 adjacent thereto, which induces an electric field in the polarization generating layer 17, in the direction from the third semiconductor layer 19 to the first semiconductor layer 16. Accordingly, due to the electric field, the top level 91 in the valence band of the polarization generating layer 17 and the bottom level 92 in the conduction band of the polarization generating layer 17 are gradually raised in the direction from the third semiconductor layer 19 to the first semiconductor layer 16.

Namely, the top levels 91 in the valence bands of the third semiconductor layer 19, the first semiconductor layer 16 and the active layer 15 are gradually raised, in the mentioned order.

Accordingly, as previously described with respect to the band diagram of the semiconductor light emitting device 901 of FIG. 2, the active layer 15 forms a quantum well with the n-side guide layer 14 and the first semiconductor layer 16 utilized as barriers.

In the semiconductor light emitting device 905, carriers move as previously described with respect to the semiconductor light emitting device 901 of FIG. 2. Namely, electrons introduced from the electrode 10 are concentrated at the bottom level 92 in the conduction band of the active layer 15, while holes introduced from the stripe-shaped electrode 22 are subjected to Coulomb forces from the electric field generated in the polarization generating layer 17 and are concentrated at the top level 91 in the valence band of the active layer 15.

Recombination of the electrons and the holes concentrated in the active layer 15 occurs, which causes the semiconductor light emitting device 905 to emit, from the active layer 15, light with a wavelength according to the band gap, which is indicated as the interval between the top level 91 in the valence band and the bottom level 92 in the conduction band of the quantum well.

Accordingly, the semiconductor light emitting device 905 can offer the same effects as those described with respect to the semiconductor light emitting device 901 of FIG. 1.

Further, even if the active layer 35 described with reference to FIG. 3 is substituted for the active layer 15 in the semiconductor light emitting device 905, the same effects as those described with respect to the semiconductor light emitting device 903 of FIG. 3 can be obtained.

### Fourth Embodiment

According to the present embodiment, there is provided a semiconductor light emitting device including an active layer which causes recombination of electrons and holes, a first semiconductor layer which is deposited on the active layer such that it lies adjacent to the p-type side thereof, has a film thickness in the range of 1 nm or more and 10 nm or less and is made of a Group III nitride based compound having a composition indicated as GaN, a superlattice layer which is deposited on the first semiconductor layer such that it lies adjacent to the side thereof opposite from the active layer and is constituted by non-doped Group III nitride based compound thin films with a composition of GaN and Group III nitride based compound thin films with a composition indicated as GaₓIn₁₋ₓN (0≦X<1) which are alternately deposited in the direction of deposition, a second semiconductor layer which is deposited on the superlattice layer such that it lies adjacent to the side thereof opposite from the first semiconductor layer and is made of a non-doped Group III nitride based compound with a composition indicated as GaN, and a third semiconductor layer which is deposited on the second semiconductor layer such that it lies adjacent to the side thereof opposite from the superlattice layer and is made of a p-type Group III nitride based compound with a composition indicated as Al_{1-y}Ga_{y}N (0≦y≦1)

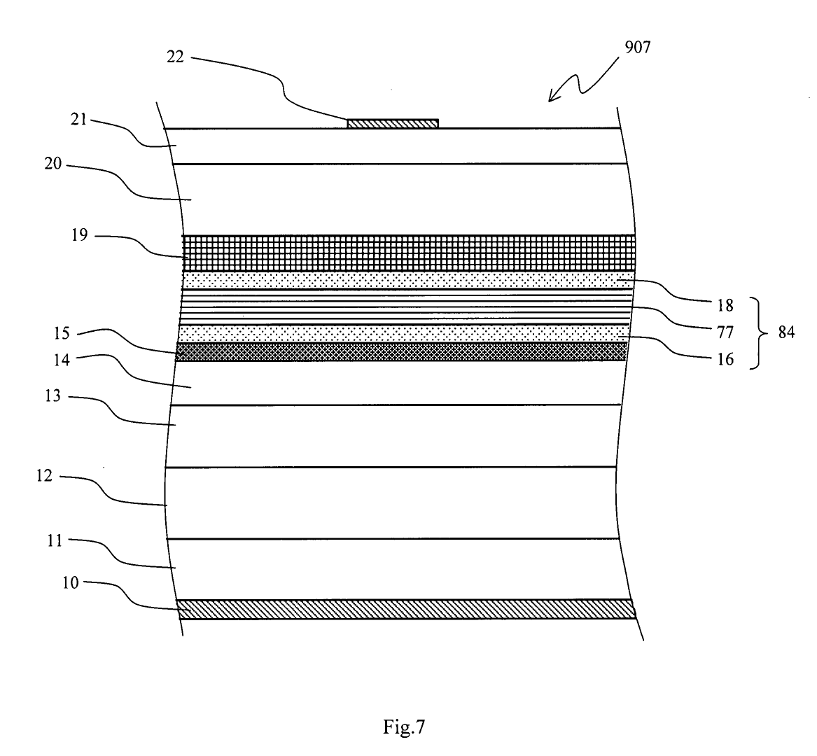

FIG. 7 illustrates a conceptual illustration of a cross section of a semiconductor light emitting device 907 according to an embodiment of the third aspect of the present invention. In FIG. 7, the same reference numerals as those used in FIG. 1 indicate the same semiconductor layers, the same substrate or the same electrodes. The semiconductor light emitting device 907 is different from the semiconductor light emitting device 901 of FIG. 1 in that the semiconductor light emitting device 907 does not include the polarization generating layer 17 in the semiconductor light emitting device 901, but includes the superlattice layer 77.

The superlattice layer 77 is a semiconductor layer having a superlattice structure constituted by plural non-doped Group III nitride based compound thin films with a wider band gap and a composition indicated as GaN (hereinafter, “the non-doped Group III nitride based compound thin films with a composition indicated as GaN in the superlattice layer 77” will be abbreviated to “the GaN thin films in the superlattice layer 77”) and plural Group III nitride based compound thin films containing In and having a band gap narrower than that of the GaN thin films in the superlattice layer 77 and a composition indicated as GaₓIn₁₋ₓN (0≦x≦1) (hereinafter, “the Group III nitride based compound thin films with a composition indicated as GaₓIn₁₋ₓN (0≦x≦1) in the superlattice layer 77” will be abbreviated to “the GaInN thin films in the superlattice layer 77”) which are alternately deposited. The GaN thin films in the superlattice layer 77 and the GaInN thin films in the superlattice layer 77 have a wurtzite crystal structure. Preferably, the GaN thin films in the superlattice layer 77 and the GaInN thin films in the superlattice layer 77 have film thicknesses in the range of 1 nm or more to 2 nm or less. The superlattice layer 77 is a semiconductor layer having the function of smoothly moving holes which are carriers.

It is desirable that the band gap of the GaInN thin films in the superlattice layer 77 is wider than the band gap of the active layer 15, in order to prevent the occurrence of recombination of carriers in the GaInN thin films in the superlattice layer 77. Namely, it is preferable that a relationship of a≦x<1 is satisfied in the composition of the GaInN thin films in the superlattice layer 77. For example, a relationship of x=0.98, namely Ga_{0.98}In_{0.02}N, can be exemplified.

Further, it is preferable that there are 10 pairs or more to 100 pairs or less of a GaN thin film and a GaInN thin film in the superlattice layer 77.

In the semiconductor light emitting device 907 of FIG. 7, there are GaInN thin films at the opposite ends of the superlattice layer 77, and the first semiconductor layer 16 and the second semiconductor layer 18 are adjacent to the GaInN thin films in the superlattice layer 77.

Further, a p-side guide layer 84 includes the first semiconductor layer 16, the superlattice layer 77 and the second semiconductor layer 18.

The superlattice layer 77 can be formed by successively and alternately depositing GaN thin films in the superlattice layer 77 and GaInN thin films in the superlattice layer 77, through a MOCVD method as described with respect to the semiconductor light emitting device 901 of FIG. 1. Accordingly, such a semiconductor light emitting device 907 can be formed by depositing, on a substrate 11, an n-type foundation layer 12, an electron supply layer 13, an n-side guide layer 14, an active layer 15, a first semiconductor layer 16, a superlattice layer 77, a second semiconductor layer 18, a third semiconductor layer 19, a hole supply layer 20 and a p-type contact layer 21, in the mentioned order, through an MOCVD method. Further, the group III nitride based compounds of the first semiconductor layer 16, the superlattice layer 77 and the second semiconductor layer 18 are deposited such that the direction of deposition is parallel to the direction of the c axis of the crystal.

Further, an electrode 10 and a stripe-shaped electrode 22 can be also formed as described with respect to the semiconductor light emitting device 901 of FIG. 1.

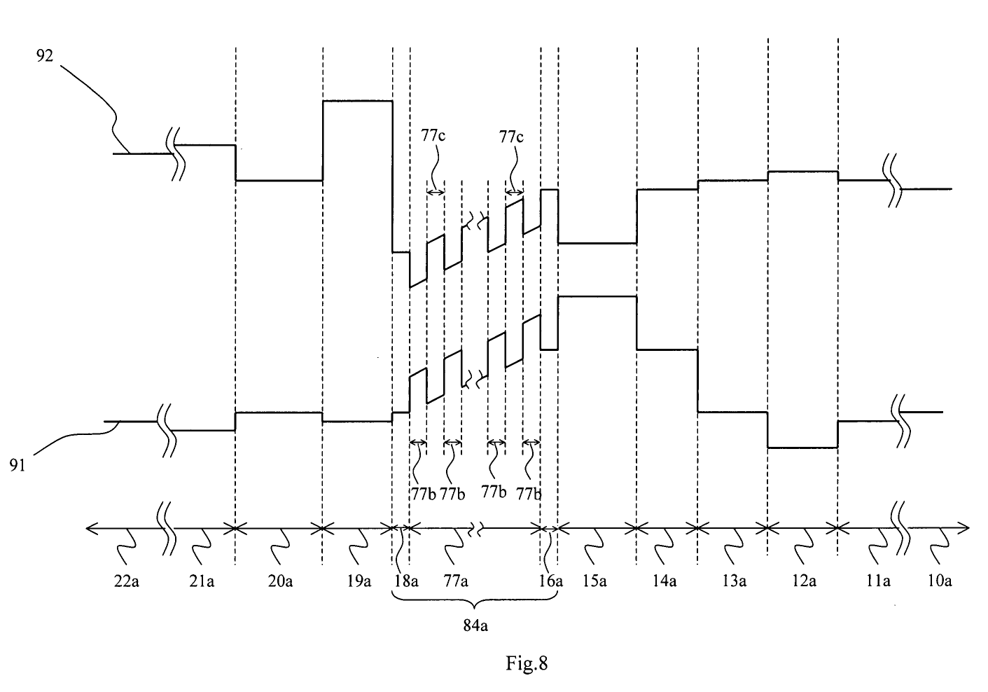

FIG. 8 illustrates a conceptual illustration of a band diagram of the semiconductor light emitting device 907. In FIG. 8, the same reference numerals as those used in the band diagram of FIG. 2 indicate the areas or the energy levels of the same semiconductor layers. FIG. 8 is different from FIG. 2 in that the band diagram of FIG. 8 does not include the area of the polarization generating layer 17 indicated by 17a in the diagram of FIG. 2, but includes the area of the superlattice layer 77 indicated by 77a. Further, the area 77a includes the areas 77b of the GaInN thin films in the superlattice layer 77 and the areas 77c of the GaN thin films in the superlattice layer 77. Further, in the band diagram of the semiconductor light emitting device 907 of FIG. 8, a portion of the area 77a of the superlattice layer 77 is not illustrated.

As previously described with reference to the band diagram of the semiconductor light emitting device 901 of FIG. 2, in the n side with respect to the active layer 15, the bottom levels 92 in the conduction bands of the electron supply layer 13, the n-side guide layer 14 and the active layer 15 are gradually lowered in the mentioned order.

The first semiconductor layer 16, the superlattice layer 77, the second semiconductor layer 18, the third semiconductor layer 19, the hole supply layer 20 and the p-type contact layer 21, which are in the p side with respect to the active layer 15, have band gaps as follows.

The first semiconductor layer 16, the second semiconductor layer 18 and the GaN thin films in the superlattice layer 77 have equal band gaps. The top levels 91 in the valence bands of the first semiconductor layer 16, the GaN thin films in the superlattice layer 77 and the second semiconductor layer 18 are gradually lowered in the mentioned order. The bottom levels 92 in the conduction bands of the first semiconductor layer 16, the GaN thin films in the superlattice layer 77 and the second semiconductor layer 18 are also gradually lowered in the mentioned order.

Polarization is generated between the GaInN thin films in the superlattice layer 77 and the GaN thin films in the superlattice layer 77, the first semiconductor layer 16 and the second semiconductor layer 18 which are adjacent to the GaInN thin films in the superlattice layer 77, which induces electric fields in the respective GaInN thin films in the superlattice layer 77, in the direction from the third semiconductor layer 19 to the first semiconductor layer 16. Accordingly, due to the electric fields, the top levels 91 in the valence bands of the GaInN thin films in the superlattice layer 77 and the bottom levels 92 in the conduction bands of the GaInN thin films in the superlattice layer 77 are gradually raised in the direction from the third semiconductor layer 19 to the first semiconductor layer 16.

The third semiconductor layer 19 contains Al in its composition and has a band gap wider than the band gap of the second semiconductor layer 18 adjacent thereto. The top levels 91 in the valence bands of the third semiconductor layer 19, the second semiconductor layer 18, the first semiconductor layer 16 and the active layer 15 are gradually raised, in the mentioned order.

As described with reference to the band diagram of the semiconductor light emitting device 901 of FIG. 2, the active layer 15 in the semiconductor light emitting device 907 forms a quantum well.

In the semiconductor light emitting device 907, carriers move as described with respect to the semiconductor light emitting device 901 of FIG. 2. Namely, electrons introduced from the electrode 10 are concentrated at the bottom level 92 in the conduction band of the active layer 15.

On the other hand, holes introduced from the stripe-shaped electrode 22 can smoothly move toward the active layer 15, through the p-type contact layer 21, the hole supply layer 20 and the third semiconductor layer 19 in which holes form majority carriers. The holes move from the third semiconductor layer 19 to the second semiconductor layer 18, as previously described with respect to the semiconductor light emitting device 901 of FIG. 2. For the same reason, holes move from the second semiconductor layer 18 to the GaInN thin film in the superlattice layer 77. The holes are subjected to Coulomb forces from the electric fields in the GaInN thin films in the superlattice layer 77 and smoothly move toward the first semiconductor layer 16. The holes which have been subjected to Coulomb forces from the electric fields in the GaInN thin films in the superlattice layer 77 can pass through the GaN thin films in the superlattice layer 77 which have a small film thickness in the range of 1 nm or more and 2 nm or less. The holes which have been subjected to Coulomb forces from the electric fields in the respective GaInN thin films in the superlattice layer 77 can pass through the first semiconductor layer 16 having a small film thickness in the range of 1 nm or more and 10 nm or less and are concentrated at the top level 91 in the valence band of the active layer 15 which forms a quantum well.

Recombination of the electrons and the holes concentrated in the active layer 15 occurs, which causes the semiconductor light emitting device 907 to emit, from the active layer 15, light with a wavelength according to the band gap, which is indicated as the interval between the top level 91 in the valence band and the bottom level 92 in the conduction band of the quantum well.

Accordingly, the semiconductor light emitting device 907 can offer the same effects as those described with respect to the semiconductor light emitting device 901 of FIG. 1.

### Fifth Embodiment

In the present embodiment, it is preferable that the active layer has a multiple quantum well structure constituted by at least two types of Group III nitride based compound thin films with different compositions indicated as AlₚGa_{q}In_{1-p-q}N (0≦p≦1, 0≦q≦1 and 0≦p+q≦1) which are alternately deposited in the direction of deposition.

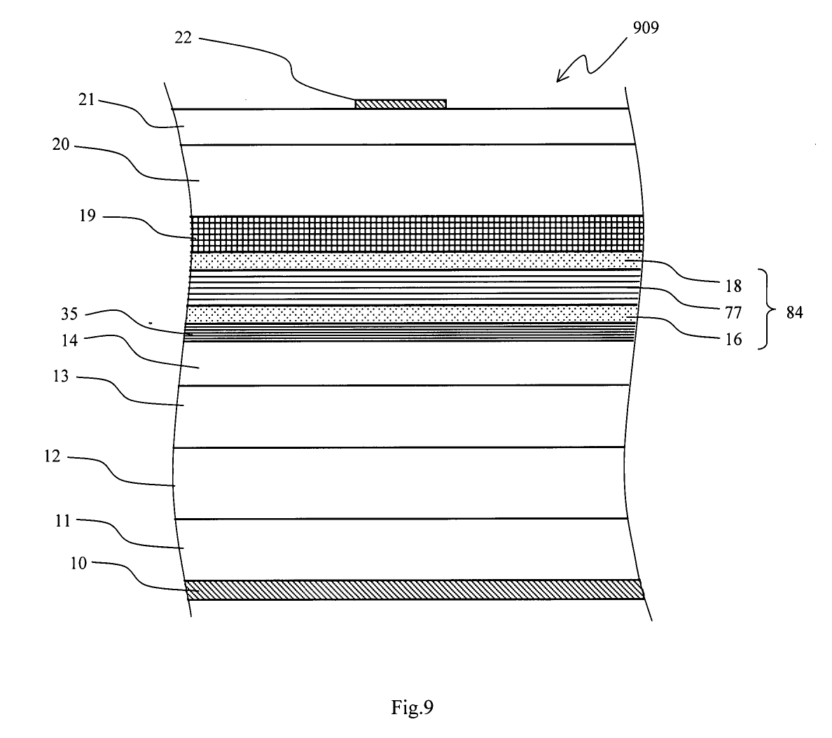

FIG. 9 illustrates a conceptual illustration of a cross section of a semiconductor light emitting device 909 according to another embodiment of the third aspect of the present invention. In FIG. 9, the same reference numerals as those used in FIG. 1, FIG. 3 and FIG. 7 indicate the same semiconductor layers, the same substrate or the same electrodes. The semiconductor light emitting device 909 is different from the semiconductor light emitting device 907 of FIG. 7 in that the semiconductor light emitting device 909 does not include the active layer 15 in the semiconductor light emitting device 907, but includes an active layer 35 as described with respect to the semiconductor light emitting device 903 of FIG. 3.

Further, in the case where the semiconductor light emitting device 909 is a semiconductor laser, it is desirable that the active layer 35 has a multiple quantum well structure constituted by Group III nitride based compound thin films with a composition of p=0 and q=1 and Group III nitride based compound thin films with a composition of p=0 and 0≦q<1 which are alternately deposited in the direction of deposition, and the Group III nitride based compound thin films with a composition of p=0 and 0≦q<1 in the active layer 35 have a band gap narrower than the band gap of the GaInN thin films in the superlattice layer 77.

In the semiconductor light emitting device 909, the active layer 35 is placed between the n-side guide layer 14 and the first semiconductor layer 16, instead of the active layer 15 in the semiconductor light emitting device 907 of FIG. 7.

Such a semiconductor light emitting device 909 can be formed by depositing, on a substrate 11, an n-type foundation layer 12, an electron supply layer 13, an n-side guide layer 14, an active layer 35, a first semiconductor layer 16, a superlattice layer 77, a second semiconductor layer 18, a third semiconductor layer 19, a hole supply layer 20 and a p-type contact layer 21, in the mentioned order, through an MOCVD method as described with respect to the semiconductor light emitting device 901 of FIG. 1. Further, the Group III nitride based compounds of the first semiconductor layer 16, the superlattice layer 77 and the second semiconductor layer 18 are deposited such that the direction of deposition is parallel to the direction of the c axis of the crystal.

Further, an electrode 10 and a stripe-shaped electrode 22 can be also formed as described with respect to the semiconductor light emitting device 901 of FIG. 1.

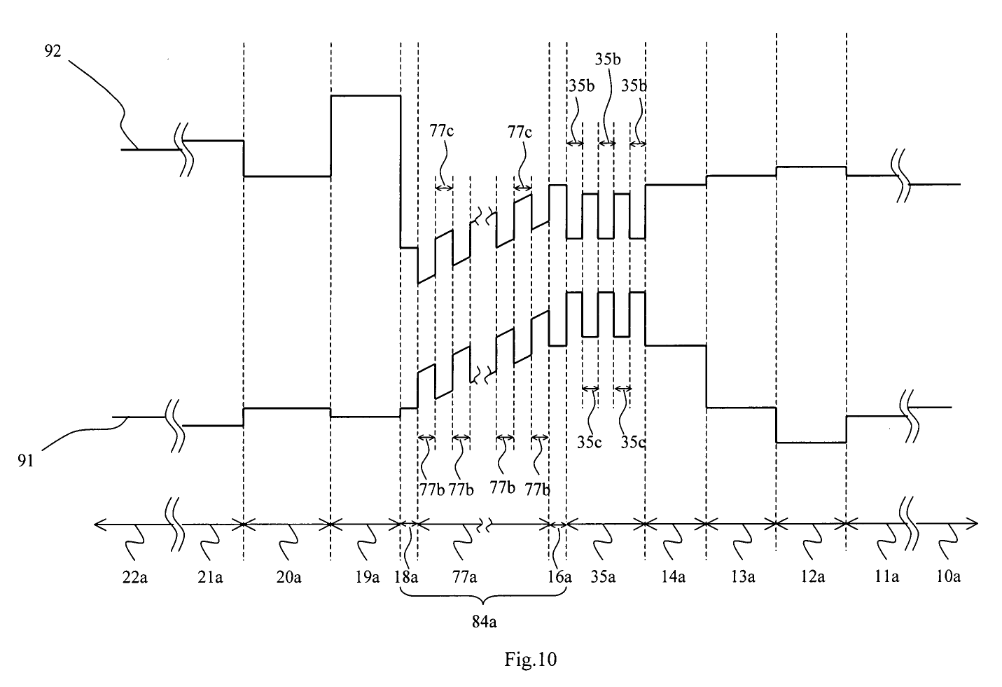

FIG. 10 illustrates a conceptual illustration of a band diagram of the semiconductor light emitting device 909. In FIG. 10, the same reference numerals as those used in the band diagrams of FIG. 2, FIG. 4 and FIG. 8 illustrate the areas or the energy levels of the same semiconductor layers. FIG. 10 is different from FIG. 8 in that the active-layer area of the active layer 35 indicated by 35a is substituted for the area of the active layer 15 illustrated by 15a. In FIG. 10, the active layer 35 includes three quantum wells. In the band diagram of the semiconductor light emitting device 909 of FIG. 10, a portion of the area 77a of the superlattice layer 77 is not illustrated.

In the area 35a of the active layer 35, 35b indicates the areas of the quantum well thin films in the active layer 35, while 35c indicates the areas of the barrier thin films in the active layer 35, wherein the quantum well thin films in the active layer 35 have a band gap narrower than the band gap of the n-side guide layer 14 and the band gap of the GaInN thin films in the superlattice layer 77.

As described with respect to the band diagram of the semiconductor light emitting device 901 of FIG. 2, in the n side with respect to the active layer 35, the bottom levels 92 in the conduction bands of the electron supply layer 13, the n-side guide layer 14 and the quantum well thin films in the active layer 35 are gradually lowered in the mentioned order.

Similarly, in the p side with respect to the active layer 35, the top levels 91 in the valence bands of the third semiconductor layer 19, the second semiconductor layer 18, the first semiconductor layer 16 and the quantum well thin films in the active layer 35 are gradually raised in the mentioned order.

In the semiconductor light emitting device 909, carriers move as described with respect to the band diagram of the semiconductor light emitting device 903 of FIG. 4. Namely, electrons introduced from the electrode 10 are concentrated at the bottom level 92 in the conduction band of the quantum well thin films in the active layer 35. Holes introduced from the stripe-shaped electrode 22 are concentrated at the top level 91 in the valence band of the quantum well thin films in the active layer 35, as described with respect to the semiconductor light emitting device 907 of FIG. 8.

Recombination of the electrons and the holes concentrated in the quantum well thin films in the active layer 35 occurs, which causes the semiconductor light emitting device 909 to emit, from the active layer 35, light with a wavelength according to the band gap, which is indicated as the interval between the top level 91 in the valence band and the bottom level 92 in the conduction band of the quantum well thin films in the active layer 35.

Accordingly, the semiconductor light emitting device 909 can offer the same effects as those described with respect to the semiconductor light emitting device 901 of FIG. 1.

### Sixth Embodiment

According to the present embodiment, there is provided a semiconductor light emitting device including an active layer which causes recombination of electrons and holes, a first semiconductor layer which is deposited on the active layer such that it lies adjacent to the p-type side thereof, has a film thickness in the range of 1 nm or more and 10 nm or less and is made of a Group III nitride based compound with a composition indicated as GaN, a superlattice layer which is deposited on the first semiconductor layer such that it lies adjacent to the side thereof opposite from the active layer and is constituted by non-doped Group III nitride based compound thin films with a composition indicated as GaN and Group III nitride based compound thin films with a composition indicated as GaₓIn₁₋ₓN (0≦X<1) which are alternately deposited in the direction of deposition, and a third semiconductor layer which is deposited on the superlattice layer such that it lies adjacent to the side thereof opposite from the first semiconductor layer and is made of a p-type Group III nitride based compound with a composition indicated as Al_{1-y}Ga_{y}N (0≦y≦1)

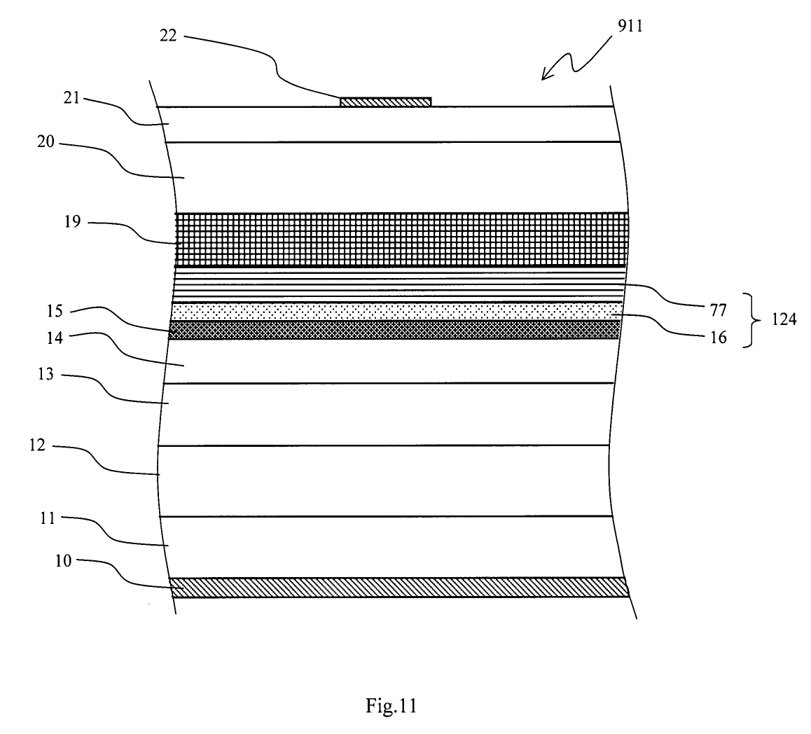

FIG. 11 illustrates a conceptual illustration of a cross section of a semiconductor light emitting device 911 according to an embodiment of the fourth aspect of the present invention. In FIG. 11, the same reference numerals as those used in FIG. 1 and FIG. 7 indicate the same semiconductor layers, the same substrate or the same electrodes. The semiconductor light emitting device 911 is different from the semiconductor light emitting device 907 in FIG. 7 in that the semiconductor light emitting device 911 does not include the second semiconductor layer 18 in the semiconductor light emitting device 907, and the superlattice layer 77 and the third semiconductor layer 19 are adjacent to each other.

Further, a p-side guide layer 124 includes the first semiconductor layer 16 and the superlattice layer 77.

Accordingly, such a semiconductor light emitting device 911 can be formed by depositing, on a substrate 11, an n-type foundation layer 12, an electron supply layer 13, an n-side guide layer 14, an active layer 15, a first semiconductor layer 16, a superlattice layer 77, a third semiconductor layer 19, a hole supply layer 20 and a p-type contact layer 21, in the mentioned order, through an MOCVD method as described with respect to the semiconductor light emitting device 901 of FIG. 1. Further, the Group III nitride based compounds of the first semiconductor layer 16, the superlattice layer 77 and the third semiconductor layer 19 are deposited such that the direction of deposition is parallel to the direction of the c axis of the crystal.

Further, an electrode 10 and a stripe-shaped electrode 22 can be also formed as described with respect to the semiconductor light emitting device 901 of FIG. 1.

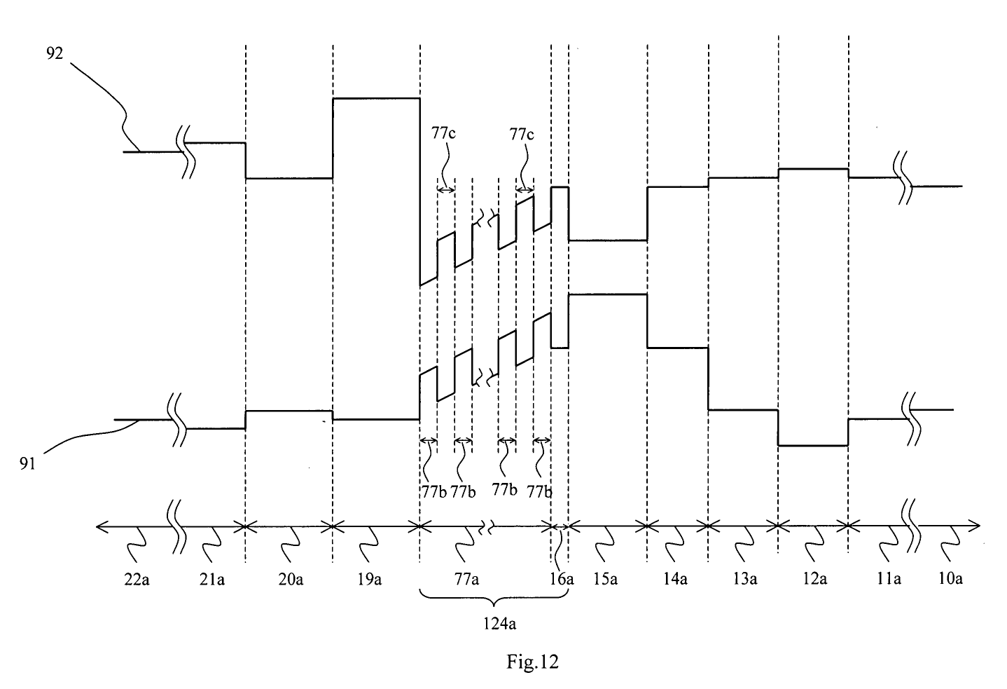

FIG. 12 illustrates a conceptual illustration of the band diagram of the semiconductor light emitting device 911. In FIG. 12, the same reference numerals as those used in the band diagrams of FIG. 2 and FIG. 8 indicate the areas or the energy levels of the same semiconductor layers. FIG. 12 is different from FIG. 8 in that the band diagram of FIG. 12 does not include the area of the second semiconductor layer 18 indicated by 18a in the band diagram of FIG. 8. Further, in the band diagram of the semiconductor light emitting device 911 of FIG. 12, a portion of the area 77a of the superlattice layer 77 is not illustrated.

As described with reference to the band diagram of the semiconductor light emitting device 901 of FIG. 2, in the n side with respect to the active layer 15, the bottom levels 92 in the conduction bands of the electron supply layer 13, the n-side guide layer 14 and the active layer 15 are gradually lowered in the mentioned order.

The first semiconductor layer 16, the superlattice layer 77, the third semiconductor layer 19, the hole supply layer 20 and the p-type contact layer 21, which are in the p side with respect to the active layer 15, have band gaps as follows.

The first semiconductor layer 16 has a band gap equal to the band gap of the GaN thin films in the superlattice layer 77. The top levels 91 in the valence bands of the first semiconductor layer 16 and the GaN thin films in the superlattice layer 77 are gradually lowered in the mentioned order. The bottom levels 92 in the conduction bands of the first semiconductor layer 16 and the GaN thin films in the superlattice layer 77 are also gradually lowered in the mentioned order.

Polarization is generated between the GaInN thin films in the superlattice layer 77 and the third semiconductor layer 19 which is adjacent to the GaInN thin films in the superlattice layer 77, which induces electric fields in the GaInN thin films in the superlattice layer 77 which are sandwiched between the third semiconductor layer 19 and the GaN thin films in the superlattice layer 77, in the direction from the third semiconductor layer 19 to the first semiconductor layer 16. Accordingly, due the electric fields, the top level 91 in the valence band and the bottom level 92 in the conduction band of the GaInN thin films in the superlattice layer 77 are gradually raised in the direction from the third semiconductor layer 19 to the first semiconductor layer 16.

Namely, the top levels 91 in the valence bands of the third semiconductor layer 19, the first semiconductor layer 16 and the active layer 15 are gradually raised in the mentioned order.

As described with respect to the band diagram of the semiconductor light emitting device 901 of FIG. 2, the active layer 15 forms a quantum well with the n-side guide layer 14 and the first semiconductor layer 16 utilized as barriers.

In the semiconductor light emitting device 911, carriers move as described with respect to the semiconductor light emitting device 901 of FIG. 2. Namely, electrons introduced from the electrode 10 are concentrated at the bottom level 92 in the conduction band of the active layer 15, while holes introduced from the stripe-shaped electrode 22 are concentrated at the top level 91 in the valence band of the active layer 15.

Recombination of the electrons and the holes concentrated in the active layer 15 occurs, which causes the semiconductor light emitting device 911 to emit, from the active layer 15, light with a wavelength according to the band gap, which is indicated as the interval between the top level 91 in the valence band and the bottom level 92 in the conduction band of the quantum well.

Accordingly, the semiconductor light emitting device 911 can offer the same effects as those described with respect to the semiconductor light emitting device 901 of FIG. 1.

Further, even if the active layer 35 described with reference to FIG. 3 is substituted for the active layer 15 in the semiconductor light emitting device 911, the same effects as those described with respect to the semiconductor light emitting device 909 of FIG. 9 can be obtained.

### Seventh Embodiment

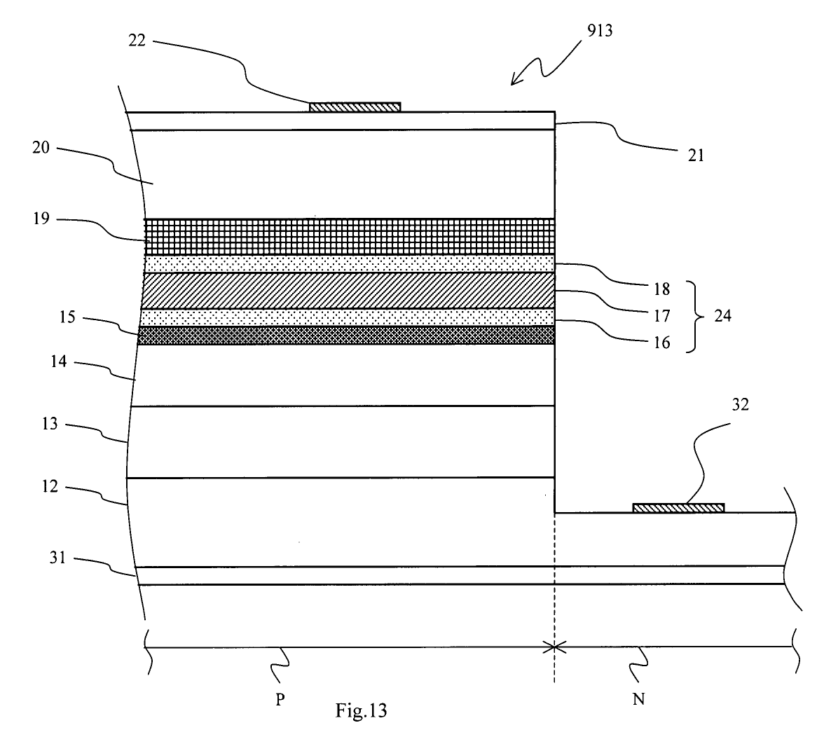

FIG. 13 illustrates a conceptual illustration of a cross section of a semiconductor light emitting device 913 according to another embodiment of the first aspect of the present invention. In FIG. 13, the same reference numerals as those used in FIG. 1 indicate the same semiconductor layers, the same substrate or the same electrodes. The semiconductor light emitting device 913 is different from the semiconductor light emitting device 901 of FIG. 1 in that the semiconductor light emitting device 913 does not include the electrode 10 and the substrate 11 in the semiconductor light emitting device 901, but includes an electrode 32 and a substrate 31. The semiconductor light emitting device 913 is a surface-electrode type semiconductor light emitting device including an electrode 32 and a stripe-shaped electrode 22 placed on the same side with respect to a substrate 31.

The substrate 31 physically supports the semiconductor light emitting device 913. As the substrate of the semiconductor light emitting device 913, a material which enables preferably semiconductor thin films to grow thereon is selected. For example, sapphire can be exemplified, in the case of depositing AlₚGa_{q}In_{1-p-q} N compounds.

The electrode 32 is placed in order to enable a voltage to apply to the semiconductor light emitting device 913. The electrode 32 has the functions described with respect to the electrode 10 of FIG. 1, and the material thereof may be, for example, Ti/Al/Ti/Au or Al/Au.

Such a semiconductor light emitting device 913 is fabricated as will be described later. Through an MOCVD method, an n-type foundation layer 12, an electron supply layer 13, an n-side guide layer 14, an active layer 15, a first semiconductor layer 16, a polarization generating layer 17, a second semiconductor layer 18, a third semiconductor layer 19, a hole supply layer 20 and a p-type contact layer 21 are deposited in the mentioned order, on the substrate 31. Further, the Group III nitride based compounds of the first semiconductor layer 16, the polarization generating layer 17 and the second semiconductor layer 18 are deposited such that the direction of deposition is parallel to the direction of the c axis of the crystal.

Subsequently, a stripe-shaped electrode 22 is formed as described with respect to the semiconductor light emitting device 901 of FIG. 1.

Then, in order to remove the semiconductor layers at a negative-electrode portion N in which the electrode 32 is to be formed, a resist pattern which covers the upper surface of a positive electrode portion P is formed using a lithography technique and, then, the semiconductor layers from the p-type contact layer 21 up to a halfway position of the film thickness of the n-type foundation layer 12 are removed from the negative electrode portion N through dry etching. Since the etching is performed up to a halfway position of the film thickness of the n-type foundation layer 12, the end point is controlled through the etching time.

After the formation of the negative electrode portion N, an electrode 32 is formed similarly to the formation of the stripe-shaped electrode 22.

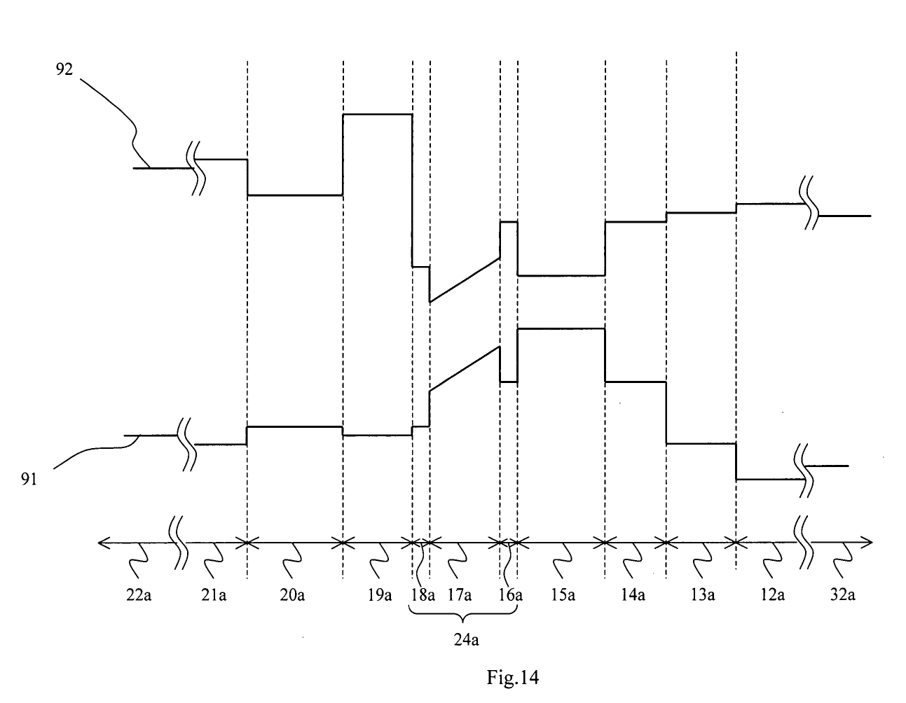

FIG. 14 illustrates a conceptual illustration of the band diagram of the semiconductor light emitting device 913. In FIG. 14, the same reference numerals as those used in FIG. 2 indicate the areas or the energy levels of the same semiconductor layers. The band diagram of the semiconductor light emitting device 913 of FIG. 14 is different from the band diagram of the semiconductor light emitting device 901 of FIG. 2 in that it does not illustrate the area 11a of the substrate 11 and the area 10a of the electrode 10, but illustrates the area 32a of the electrode 32. In FIG. 14, portions of the band gaps of the p-type contact layer 21 to the stripe-shaped electrode 22 and portions of the band gaps of the n-type foundation layer 12 to the electrode 32 are not illustrated.

By applying a voltage to the semiconductor light emitting device 913 using the stripe-shaped electrode 22 as a positive electrode while using the electrode 32 as a negative electrode, electrons are introduced to the semiconductor light emitting device 913 from the electrode 32 while holes are introduced thereto from the stripe-shaped electrode 22.

The electrons introduced from the electrode 32 are concentrated in the active layer 15 in the semiconductor light emitting device 913, as described with respect to the band diagram of the semiconductor light emitting device 901 of FIG. 2.

On the other hand, the holes introduced from the stripe-shaped electrode 22 are concentrated in the active layer 15 in the semiconductor light emitting device 913, as described with respect to the band diagram of the semiconductor light emitting device 901 of FIG. 2. Consequently, the semiconductor light emitting device 913 emits, from the active layer 15, light with a wavelength according to the band gap, which is indicated as the interval between the top level 21 in the valence band and the bottom level 22 in the conduction band of the active layer 15.

Accordingly, the semiconductor light emitting device 913 can offer the same effects as those described with respect to the semiconductor light emitting device 901 of FIG. 1.

Further, the semiconductor light emitting devices according to the second aspect of the present invention, the third aspect of the present invention and the fourth aspect of the present invention can be formed to be of a surface electrode type as described with respect to the semiconductor light emitting device 913.

The structures of the semiconductor light emitting devices according to the present invention can be utilized as light receiving devices. Also, they can be utilized as electronic devices such as transistors, diodes and the like and compound high frequency electronic devices as represented by HEMT (High Electron Mobility Transistor).

What is clamed is:

1. A semiconductor light emitting device comprising:
an active layer which causes recombination of electrons and holes;
a first semiconductor layer which is deposited on said active layer such that it lies adjacent to the p-type side of said active layer, has a thickness in the direction of deposition in the range of 1 nm or more and 10 nm or less and is made of a Group III nitride based compound with a composition indicated as GaN;
a polarization generating layer which is deposited on said first semiconductor layer such that it lies adjacent to the opposite side of said first semiconductor layer from said active layer, has a thickness in the direction of deposition in the range of 5 nm or more and 100 nm or less and is made of a Group III nitride based compound with a composition indicated as GaₓIn₁₋ₓN (0≦X<1);
a second semiconductor layer which is deposited on said polarization generating layer such that it lies adjacent to the opposite side of said polarization generating layer from said first semiconductor layer and is made of a non-doped Group III nitride based compound with a composition indicated as GaN; and
a third semiconductor layer which is deposited on said second semiconductor layer such that it lies adjacent to the opposite side of said second semiconductor layer from said polarization generating layer and is made of a p-type Group III nitride based compound with a composition indicated as Al_{1-y}Ga_{y}N (0≦y≦1).

2. A semiconductor light emitting device comprising:
an active layer which causes recombination of electrons and holes;
a first semiconductor layer which is deposited on said active layer such that it lies adjacent to the p-type side of said active layer, has a thickness in the direction of deposition in the range of 1 nm or more and 1 nm or less and is made of a Group III nitride based compound with a composition indicated as GaN;
a polarization generating layer which is deposited on said first semiconductor layer such that it lies adjacent to the side of said first semiconductor layer opposite from said active layer, has a thickness in the direction of deposition in the range of 5 nm or more and 100 nm or less and is made of a Group III nitride based compound with a composition indicated as GaₓIn₁₋ₓN (0≦X<1); and
a third semiconductor layer which is deposited on said polarization generating layer such that it lies adjacent to the side of said polarization generating layer opposite from said first semiconductor layer and is made of a p-type Group III nitride based compound with a composition indicated as Al_{1-y}Ga_{y}N (0≦y≦1).

3. A semiconductor light emitting device comprising:
an active layer which causes recombination of electrons and holes;
a first semiconductor layer which is deposited on said active layer such that it lies adjacent to the p-type side of said active layer, has a thickness in the direction of deposition in the range of 1 nm or more and 10 nm or less and is made of a Group III nitride based compound with a composition indicated as GaN;
a superlattice layer which is deposited on said first semiconductor layer such that it lies adjacent to the side of said first semiconductor layer opposite from said active layer and is constituted by non-doped Group III nitride based compound thin films with a composition of GaN and Group III nitride based compound thin films with a composition indicated as GaₓIn₁₋ₓN (0≦X<1) which are alternately deposited in the direction of deposition;
a second semiconductor layer which is deposited on said superlattice layer such that it lies adjacent to the side of said superlattice layer opposite from said first semiconductor layer and is made of a non-doped Group III nitride based compound with a composition indicated as GaN; and
a third semiconductor layer which is deposited on said second semiconductor layer such that it lies adjacent to the side of said second semiconductor layer opposite from said superlattice layer and is made of a p-type Group III nitride based compound with a composition indicated as Al_{1-y}Ga_{y}N (0≦y≦1).

4. A semiconductor light emitting device comprising:
an active layer which causes recombination of electrons and holes;
a first semiconductor layer which is deposited on said active layer such that it lies adjacent to the p-type side of said active layer, has a thickness in the direction of deposition in the range of 1 nm or more and 10 nm or less and is made of a Group III nitride based compound with a composition indicated as GaN;
a superlattice layer which is deposited on said first semiconductor layer such that it lies adjacent to the side of said first semiconductor layer opposite from said active layer and is constituted by non-doped Group III nitride based compound thin films with a composition indicated as GaN and Group III nitride based compound thin films with a composition indicated as GaₓIn₁₋ₓN (0≦X<1) which are alternately deposited in the direction of deposition; and
a third semiconductor layer which is deposited on said superlattice layer such that it lies adjacent to the side of said superlattice layer opposite from said first semiconductor layer and is made of a p-type Group III nitride based compound with a composition indicated as Al_{1-y}Ga_{y}N (0≦y≦1).

5. The semiconductor light emitting device according to claim 3,
wherein said superlattice layer includes 10 pairs or more and 100 pairs or less of a non-doped Group III nitride based compound thin film with a composition indicated as GaN and a III nitride compound thin film with a composition indicated as GaₓIn₁₋ₓN (0≦x<1).

6. The semiconductor light emitting device according to claim 4,
wherein said superlattice layer includes 10 pairs or more and 100 pairs or less of a non-doped Group III nitride based compound thin film with a composition indicated as GaN and a III nitride compound thin film with a composition indicated as GaₓIn₁₋ₓN (0≦x<1).

7. The semiconductor light emitting device according to claim 1,
wherein said active layer has a multiple quantum well structure constituted by at least two types of Group III nitride based compound thin films with different compositions indicated as AlₚGa_{q}In_{1-p-q}N (0≦p≦1, 0≦q≦1 and 0≦p+q≦1) which are alternately deposited in the direction of deposition.

8. The semiconductor light emitting device according to claim 2,
wherein said active layer has a multiple quantum well structure constituted by at least two types of Group III nitride based compound thin films with different compositions indicated as AlₚGa_{q}In_{1-p-q}N (0≦p≦1, 0≦q≦1 and 0≦p+q≦1) which are alternately deposited in the direction of deposition.

9. The semiconductor light emitting device according to claim 3,
wherein said active layer has a multiple quantum well structure constituted by at least two types of Group III nitride based compound thin films with different compositions indicated as AlₚGa_{q}In_{1-p-q}N (0≦p≦1, 0≦q≦1 and 0≦p+q≦1) which are alternately deposited in the direction of deposition.

10. The semiconductor light emitting device according to claim 4,
wherein said active layer has a multiple quantum well structure constituted by at least two types of Group III nitride based compound thin films with different compositions indicated as AlₚGa_{q}In_{1-p-q}N (0≦p≦1, 0≦q≦1 and 0≦p+q≦1) which are alternately deposited in the direction of deposition.

11. The semiconductor light emitting device according to claim 7,
wherein said active layer has a multiple quantum well structure constituted by Group III nitride based compound thin films with relationships of p=0 and q=1 in said composition and Group III nitride based compound thin films with relationships of p=0 and 0≦q<1 in said composition which are alternately deposited in the direction of deposition, and the Group III nitride based compound thin films with relationships of p=0 and 0≦q<1 in said composition in said active layer have a band gap narrower than the band gap of said polarization generating layer or the band gap of the Group III nitride based compound thin films with a composition indicated as GaₓIn₁₋ₓN (0≦x<1) in said superlattice layer.

12. The semiconductor light emitting device according to claim 8,
wherein said active layer has a multiple quantum well structure constituted by Group III nitride based compound thin films with relationships of p=0 and q=1 in said composition and Group III nitride based compound thin films with relationships of p=0 and 0≦q<1 in said composition which are alternately deposited in the direction of deposition, and the Group III nitride based compound thin films with relationships of p=0 and 0≦q<1 in said composition in said active layer have a band gap narrower than the band gap of said polarization generating layer or the band gap of the Group III nitride based compound thin films with a composition indicated as GaₓIn₁₋ₓN (0≦x<1) in said superlattice layer.

13. The semiconductor light emitting device according to claim 9,
wherein said active layer has a multiple quantum well structure constituted by Group III nitride based compound thin films with relationships of p=0 and q=1 in said composition and Group III nitride based compound thin films with relationships of p=0 and 0≦q<1 in said composition which are alternately deposited in the direction of deposition, and the Group III nitride based compound thin films with relationships of p=0 and 0≦q<1 in said composition in said active layer have a band gap narrower than the band gap of said polarization generating layer or the band gap of the Group III nitride based compound thin films with a composition indicated as GaₓIn₁₋ₓN (0≦x<1) in said superlattice layer.

14. The semiconductor light emitting device according to claim 10,
wherein said active layer has a multiple quantum well structure constituted by Group III nitride based compound thin films with relationships of p=0 and q=1 in said composition and Group III nitride based compound thin films with relationships of p=0 and 0≦q<1 in said composition which are alternately deposited in the direction of deposition, and the Group III nitride based compound thin films with relationships of p=0 and 0≦q<1 in said composition in said active layer have a band gap narrower than the band gap of said polarization generating layer or the band gap of the Group III nitride based compound thin films with a composition indicated as GaₓIn₁₋ₓN (0≦x<1) in said superlattice layer.

15. The semiconductor light emitting device according to claim 1,
wherein the Group III nitride based compounds of said first to third semiconductor layers have wurtzite crystal structures, and the direction of deposition of said first to third semiconductor layers is parallel to the directions of the c axes of the crystals of the Group III nitride based compounds of said first to third semiconductor layers.

16. The semiconductor light emitting device according to claim 2,
wherein the Group III nitride based compounds of said first to third semiconductor layers have wurtzite crystal structures, and the direction of deposition of said first to third semiconductor layers is parallel to the directions of the c axes of the crystals of the Group III nitride based compounds of said first to third semiconductor layers.

17. The semiconductor light emitting device according to claim 3,
wherein the Group III nitride based compounds of said first to third semiconductor layers have wurtzite crystal structures, and the direction of deposition of said first to third semiconductor layers is parallel to the directions of the c axes of the crystals of the Group III nitride based compounds of said first to third semiconductor layers.

18. The semiconductor light emitting device according to claim 4,
wherein the Group III nitride based compounds of said first to third semiconductor layers have wurtzite crystal structures, and the direction of deposition of said first to third semiconductor layers is parallel to the directions of the c axes of the crystals of the Group III nitride based compounds of said first to third semiconductor layers.
